(19) United States
(12) Patent Application Publication
(10) Pub. No.: US 2024/0237205 A9
(43) Pub. Date: Jul. 11, 2024

(54) DEVICES, SYSTEMS, AND METHODS FOR MAKING AND USING CIRCUIT ASSEMBLIES HAVING PATTERNS OF DEFORMABLE CONDUCTIVE MATERIAL FORMED THEREIN

(71) Applicant: Liquid Wire, LLC, Portland, OR (US)

(72) Inventors: Mark S. Kruskopf, Portland, OR (US); Katherine M. Nelson, Portland, OR (US); Jesse Michael Martinez, Portland, OR (US); Michael Austin Clarke, Tigard, OR (US); Mark William Ronay, Portland, OR (US)

(73) Assignee: Liquid Wire, LLC, Portland, OR (US)

(21) Appl. No.: 18/548,211

(22) PCT Filed: Feb. 25, 2022
(86) PCT No.: PCT/US22/70853

§ 371 Date: Aug. 28, 2023

Related U.S. Application Data
(60) Provisional application No. 63/154,665, filed on Feb. 26, 2021.

(51) Int. Cl. H05K 1/09; H05K 3/12; H05K 3/46

(52) U.S. Cl. CPC H05K 1/09; H05K 3/1225; H05K 3/1258; H05K 3/4664; H05K 2201/032; H05K 2201/10689

(57) ABSTRACT

Devices, systems, and methods for making and using circuit assemblies having a pattern of deformable conductive material formed therein are disclosed herein. In various aspects, a circuit assembly can include a substrate layer; a first pattern of deformable conductive material formed on a surface of the substrate layer using a removable stencil; and a first stacked layer configured to cover at least a portion of the first pattern of deformable conductive material.

### FIELD

The present disclosure generally relates to electronic circuits and more specifically to devices, systems, and methods for making and using circuit assemblies having patterns of deformable conductive material formed therein.

### SUMMARY

The following summary is provided to facilitate an understanding of some of the innovative features unique to the aspects disclosed herein, and is not intended to be a full description. A full appreciation of the various aspects can be gained by taking the entire specification, claims, and abstract as a whole.

In various aspects, a method for manufacturing a circuit assembly is disclosed. In one aspect, the method includes providing a substrate layer including a substrate material; placing a stencil including a stencil material on a surface of the substrate layer, wherein the stencil has a thickness and a pattern of passages formed therein; depositing a deformable conductive material to at least partially fill the pattern of passages; removing the removable stencil from the surface of the substrate layer to leave a first pattern of deformable conductive material formed on the substrate layer, wherein the first pattern of deformable conductive material can include at least one gap; covering at least a portion of the first pattern of deformable conductive material with a first stacked layer, wherein the first stacked layer is an insulation layer, an encapsulation layer, or a combination thereof; and healing the at least one gap, wherein unitizing the circuit assembly causes the at least one gap to heal.

In various aspects, a circuit assembly is disclosed. In one aspect, the circuit assembly includes a substrate layer; a first pattern of deformable conductive material formed on a surface of the substrate layer using a removable stencil; and a first stacked layer configured to cover at least a portion of the first pattern of deformable conductive material.

These, and other objects, features, and characteristics of the present disclosure, as well as the methods of operation, and functions of the related elements of structure, and the combination of parts, and economies of manufacture, will become more apparent upon consideration of the following description, and the appended claims with reference to the accompanying drawings, all of which form a part of this specification. It is to be expressly understood, however, that the drawings are for the purpose of illustration and description only, and are not intended as a definition of the limits of the invention.

### BRIEF DESCRIPTION OF THE DRAWINGS

Various features of the aspects described herein are set forth with particularity in the appended claims. The various aspects, however, both as to organization, and methods of operation, together with advantages thereof, may be understood in accordance with the following description taken in conjunction with the accompanying drawings as follows:

FIG. 1 is an exploded perspective view of a circuit assembly, in accordance with at least one non-limiting aspect of the present disclosure;

FIG. 2 is an exploded partial perspective view of a circuit assembly, in accordance with at least one non-limiting aspect of the present disclosure;

FIGS. 3A-3E are cross-sectional views taken through line A-A in FIG. 2 showing exemplary implementation details and aspects of the circuit assembly of FIG. 2, in accordance with at least one non-limiting aspect of the present disclosure;

FIG. 4 is an exploded partial perspective view of a circuit assembly, in accordance with at least one non-limiting aspect of the present disclosure;

FIGS. 5A-5C are cross-sectional views taken through line B-B in FIG. 4 showing exemplary implementation details and aspects of the circuit assembly of FIG. 4, in accordance with at least one non-limiting aspect of the present disclosure;

FIG. 6 is an exploded partial perspective view of a circuit assembly, in accordance with at least one non-limiting aspect of the present disclosure;

FIGS. 7A and 7B through 15A and 15B illustrate various aspects of stacked circuit assemblies and methods for their fabrication, in accordance with at least one non-limiting aspect of the present disclosure;

FIG. 16 is a cross-sectional view illustrating a circuit assembly, in accordance with at least one non-limiting aspect of the present disclosure;

FIG. 17 is a cross-sectional view illustrating a circuit assembly, in accordance with at least one non-limiting aspect of the present disclosure;

FIGS. 18A and 18B through 23A and 23B illustrate various aspects of stacked circuit assemblies and methods for their fabrication, including the use of a removable stencil, in accordance with at least one non-limiting aspect of the present disclosure;

FIG. 24 is a plan view of an exemplary removable stencil, in accordance with at least one non-limiting aspect of the present disclosure;

FIGS. 25 and 26 are detailed views of the exemplary removable stencil of FIG. 24, in accordance with at least one non-limiting aspect of the present disclosure.

FIG. 27 is a flow diagram of a method for reclaiming material from a highly sustainable circuit assembly, in accordance with at least one-non limiting aspect of the present disclosure; and

FIG. 28 is a flow diagram of a method for recycling a reclaimed deformable conductive material, in accordance with at least one-non limiting aspect of the present disclosure.

FIG. 29 is a flow diagram of a method for manufacturing a highly sustainable circuit assembly, in accordance with at least one-non limiting aspect of the present disclosure.

Corresponding reference characters indicate corresponding parts throughout the several views. Numeric reference characters followed by letters (e.g. 20A, 20B, etc.) can indicate varying instances of corresponding parts throughout the several views. The exemplifications set out herein illustrate various aspects of the present disclosure, in one form, and such exemplifications are not to be construed as limiting the scope of the disclosure in any manner.

### DETAILED DESCRIPTION

The present application is related to the following commonly owned patent applications, the disclosures of which are hereby incorporated by reference in their entirety:
International Patent Application No; PCT/US2017/019762 titled LIQUID WIRE, which was filed on Feb. 27, 2017 and published on Sep. 8, 2017 as International Patent Publication No. WO2017/151523A1;
U.S. patent application Ser. No. 16/548,379 titled STRUCTURES WITH DEFORMABLE CONDUCTORS, which was filed on Aug. 22, 2019 and granted as U.S. Pat. No. 11,088,063 on Aug. 10, 2021;
U.S. patent application Ser. No. 17/192,725 titled DEFORMABLE INDUCTORS, which was filed Mar. 4, 2021;
International Patent Application No. PCT/US2021/071374 titled WEARABLE ARTICLE WITH FLEXIBLE INDUCTIVE PRESSURE SENSOR, which was filed Sep. 3, 2021;
U.S. Provisional Patent Application No. 63/243,206 titled SUSTAINABLE INFLATABLE CIRCUITS AND METHODS FOR MAKING THEM, which was filed Sep. 13, 2021;
U.S. Provisional Patent Application No. 63/261,266 titled STRETCHABLE AND FLEXIBLE METAL FILM STRUCTURES, which was filed Sep. 21, 2021;
U.S. Provisional Application No. 63/270,589 titled FLEXIBLE THREE-DIMENSIONAL ELECTRONIC COMPONENT, which was filed Oct. 22, 2021; and
U.S. Provisional Patent Application No. 63/272,487, titled DEVICES, SYSTEMS, AND METHODS FOR MAKING AND USING A FLUID-FILLABLE CIRCUIT, which was filed Oct. 27, 2021.

According to some non-limiting aspects, the subject matter disclosed in U.S. patent application Ser. No. 11/107,354 titled FLUID-FILLED BLADDER FOR FOOTWEAR AND OTHER APPLICATIONS, which was filed on Apr. 14, 2004 and granted on Jul. 22, 2009 as U.S. Pat. No. 7,401,369; the disclosure of which is hereby incorporated by reference in its entirety, is relevant to the devices, systems, and methods disclosed herein.

Numerous specific details are set forth to provide a thorough understanding of the overall structure, function, manufacture, and use of the aspects as described in the disclosure and illustrated in the accompanying drawings. Well-known operations, components, and elements have not been described in detail so as not to obscure the aspects described in the specification. The reader will understand that the aspects described and illustrated herein are non-limiting aspects, and thus it can be appreciated that the specific structural and functional details disclosed herein may be representative and illustrative. Variations and changes thereto may be made without departing from the scope of the claims.

In the following description, like reference characters designate like or corresponding parts throughout the several views of the drawings. Also in the following description, it is to be understood that such terms as “forward”, “rearward”, “left”, “right”, “upwardly”, “downwardly”, and the like are words of convenience and are not to be construed as limiting terms.

A portion of the disclosure of this patent document contains material which is subject to copyright protection. The copyright owner has no objection to the facsimile reproduction by anyone of the patent disclosure, as it appears in the Patent and Trademark Office patent files or records, but otherwise reserves any and all copyrights disclosed herein.

Conventional methods of depositing conductive materials to traditional printed circuit boards lack efficiency because these methods can require multiple operations that are high in resource consumption and produce a great deal of waste. For example, the production of FR4/copper circuit boards typically involve various curing, etching, stripping, and soldering steps that consume electricity and water and generate spent waste materials. As just one example, in the case of etching, excess copper conductor is often treated as waste after it is removed from the circuit board assembly. Moreover, spent materials, such as etching solutions, stripping solutions, solder dross, and wastewater treatment sludge, are often hazardous waste.

Yet further, even circuit board production methods that employ conductive adhesives (e.g., conductive epoxies such as silver epoxy) to replace soldering can lack efficiency. For example, conductive epoxies typically cure shortly after being applied to a circuit board assembly. This curing reaction often prevents excess conductive epoxy from being reworked or reused because the epoxy's conductive performance deteriorates if reworked after curing. Thus, excess conductive epoxy is often wasted. Moreover, cleaning solutions are often expended when removing excess conductive epoxy from the circuit board.

Various attempts have been made to improve the efficiency of traditional printed circuit boards. For example, the Environmental Protection Agency (“EPA”) has published a summary titled Workshop Materials on WEEE Management in Taiwan, Handout 10, October 2012, the disclosure of which is hereby incorporated by reference in its entirety, which provides more details related to the waste generation and recycling processes for conventional printed circuit boards. However, these recycling processes can be expensive, time consuming, and inefficient. Additionally, some conventional methods of producing printed circuit boards can involve excessive materials and/or a layered construction that add to the inefficiency of the assembly process. For example, some methods of producing circuits using a deformable conductor may require the use of intermediate layers configured to contain the deformable conductor prior to encapsulation. Aside from containing the conductor prior to encapsulation, such intermediate layers can result in the unnecessary consumption of resources.

Accordingly, there is a need for devices, systems, and methods for making and using highly efficient circuit assemblies. Making and using highly efficient circuit assemblies can not only reduce resource expenditure, minimize waste, and substantially eliminate hazardous byproducts produced during manufacturing compared to traditional methods, such highly efficient circuit boards can include components that are non-hazardous, readily reclaimable, and/or readily recyclable. These non-hazardous, readily reclaimable, and/or readably recyclable materials can be reused in the production of additional circuit assemblies, thus decreasing the need for new raw materials. The present disclosure presents such devices, systems, and methods for making and using highly efficient circuit assemblies.

Several aspects of devices, systems, and methods for making and using circuit assemblies including various components such as, for example, substrates, layers, stacks, contact points, traces, and electrical components (e.g., integrated circuits) are disclosed herein. The various aspects (e.g., features, components, materials, methods) disclosed with respect to a particular circuit assembly disclosed herein may be applied to or combined with any of the other disclosed circuit assemblies and/or methods.

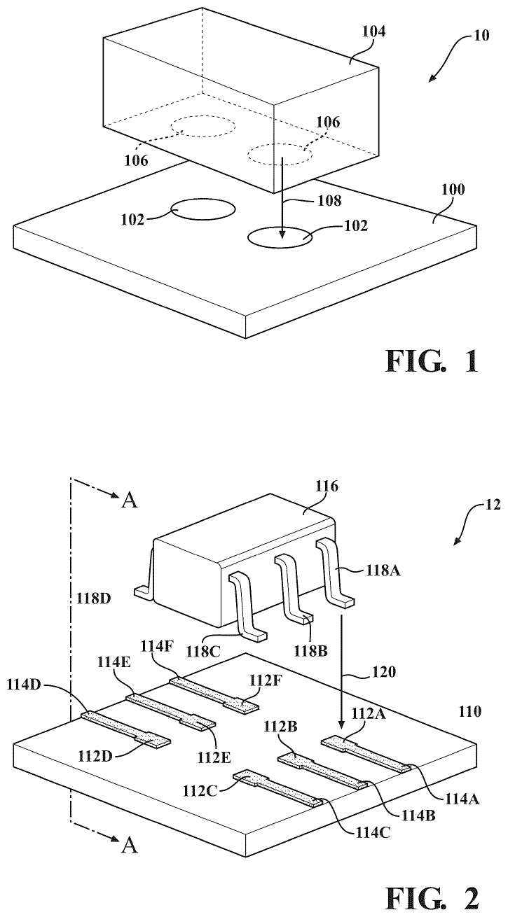

According to some non-limiting aspects, the efficient devices, systems, and methods described herein can implicate the devices, systems, and methods disclosed in U.S. Provisional Patent Application No. 63/154,665, titled HIGHLY SUSTAINABLE CIRCUITS AND METHODS FOR MAKING THEM, filed Feb. 26, 2021, the disclosure of which is hereby incorporated by reference in its entirety. For example, referring to FIG. 1, an exploded perspective view of a circuit assembly 10 is depicted in accordance with at least one non-limiting aspect of the present disclosure. The circuit assembly 10 can include a substrate layer 100 including a pattern of contact points 102. According to the non-limiting aspect of FIG. 1, two contact points 102 are depicted. However, in other aspects, the pattern of contact points 102 can include any number and arrangement of contact points, including a single contact point. The pattern of contact points 102 can be supported by the substrate 100. The pattern of contact points 102 can be formed from a readily reclaimable, deformable conductive material.

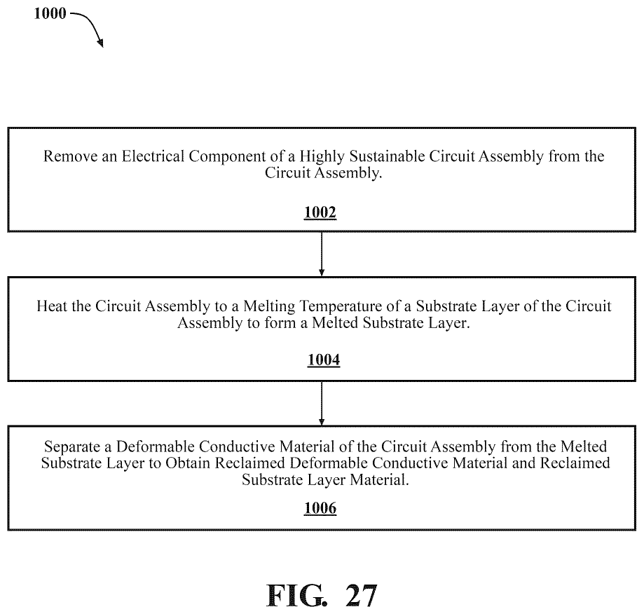

As used herein, the term “readily reclaimable” can mean that the material may be reclaimed from a circuit assembly: (i) without intensive use of resources, such as water; (ii) using relatively low energy input; and/or (iii) using techniques and methods that do not result in significant waste and/or loss of the material. A method that does not result in significant waste and/or loss of material can mean no less than 60 wt. % of the material is wasted and/or lost during the reclaiming process, such as, for example, no less than 70 wt. %, 80 wt. (X), 90 wt. %, 95 wt. %, 96 wt. (X), 97 wt. %, 98 wt. %, 99 wt. (X), 99.5 wt. %, or 99.9 wt. % of the material is wasted and/or lost during the reclamation process. An exemplary reclamation process is described below with respect to FIG. 27. A readily reclaimable material can be a readily recyclable material.

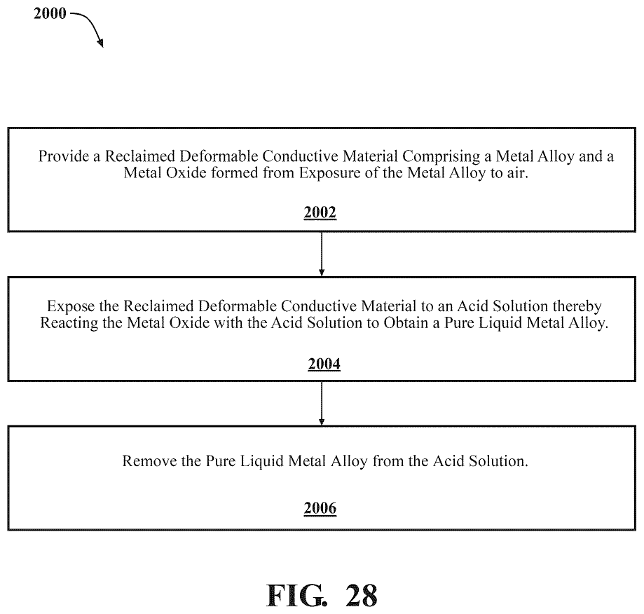

As used herein, the term “readily recyclable” can mean that a material can be processed for re-use in further manufacturing or other industrial uses. For example, “readily recyclable materials can include any material whose scrap can be readily reprocessed to form an article that is substantially the same material as virgin, previously unused stock such as a thermoplastic (e.g., thermoplastic polyurethane, polymers, acrylics, polyesters, polypropylenes, polystyrenes, nylons, Teflon, etc.). According to some non-limiting aspects a material may be readily recyclable if no less than 55 wt. % of the material used to originally manufacture the subsequently reclaimed material can be reprocessed and reused, such as, for example, no less than 60 wt. %, 65 wt,%, 70 wt. %, 75 wt. %, 80 wt. %, 85 wt. %, 90 wt. %, or no less than 95 wt. % of the material used to originally manufacture the subsequently reclaimed material can be reprocessed and reused. By reclaiming and reprocessing readily reclaimable, readily recyclable materials, the need to produce new base materials may generally be reduced. An exemplary recycling process for a readily recyclable material is described below with respect to FIG. 28.

As used herein, the term “deformable conductive material” may refer to a material such as those disclosed in the aforementioned International Patent Application No. PCT/US2017/019762 titled LIQUID WIRE, which was filed on Feb. 27, 2017 and published on Sep. 8, 2017 as International Patent Publication No. WO2017/151523A1, the disclosure of which is herein incorporated by reference in its entirety. For example, a deformable conductive material can include a variety of forms, such as a liquid, a paste, a gel, and/or a powder, amongst others, that has a deformable (e.g., soft, flexible, stretchable, bendable, elastic, flowable viscoelastic, Newtonian, non-Newtonian, etc.) quality.

Ira various aspects, a deformable conductive material can include an electroactive material, such as a deformable conductor produced from a conductive gel (e.g., a gallium indium alloy). The conductive gel can have a shear thinning composition and, according to some aspects, can include a mixture of materials in a desired ratio.

In various aspects, the conductive gel can include a mixture of a eutectic gallium alloy and gallium oxide, wherein the mixture of eutectic gallium alloy and gallium oxide has a weight percentage (wt, %) in a range of 59.9% and 99.9% eutectic gallium alloy, such as a range of 67% and 90%; and a wt. % in a range of 0.1% and 2.0% gallium oxide such as a range of 0.2 and 1%. For example, the mixture of eutectic gallium alloy and gallium oxide can have 60%, 61%, 62%, 63%, 64%, 65%, 66%, 67%, 68%, 69%, 70%, 71%, 72%, 73%, 74%, 75%, 76%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, 99%, or greater, such as 99.9% eutectic gallium alloy; and 0.1%; 0.2%, 0.3%, 0.4%, 0.5%, 0.6%, 0.7%, 0.8%, 0.9%, 1.0%, 1.1% 1.2%, 1.3%, 1.4%. 1.5%, 1.6%, 1.7%, 1.8%, 1.9%, and 2.0% gallium oxide.

In various aspects, the eutectic gallium alloy can include gallium-indium or gallium-indium-tin in any ratio of elements. In some aspects, a eutectic gallium alloy includes gallium and indium. In one aspect, the gallium-indium alloy has a wt. % of gallium a range of 40% and 95%, such as, for example, 40%, 41%, 42%, 43%, 44%, 45%, 46%, 47%, 48%, 49%, 50%, 51%, 52%, 53%, 54%, 55%. 56%, 57%, 58%, 59%, 60%, 61%, 62%, 63%, 64%, 65%, 66%, 67%, 68%. 69%, 70%, 71%, 72%, 73%, 74%, 75%, 76%, 77%, 78%, 79%, 80%, 81%, 82%, 83%, 84%, 85%, 86%, 87%, 88%, 89%. 90%, 91%. 92%, 93%, 94%, or 95%, In one aspect, the gallium-indium alloy has a wt. % of indium in the range of 5% and 60%, such as, for example 5%, 6%, 7%, 8%, 9%, 10%. 11%, 12%, 13%, 14%, 15%, 16%, 17%, 18%, 19%. 20%, 21%, 22%, 23%, 24%, 25%, 26%, 27%, 28%, 29%, 30%, 31%, 32%, 33%. 34%, 35%, 36%, 37%, 38%, 39%, 40%, 41%, 42%, 43%, 44%, 45%, 46%, 47%, 48%, 49%, 50%, 51%, 52%, 53%, 54%, 55%, 56%. 57%, 58%, 59%, or 60%, In some aspects, a eutectic gallium alloy includes gallium and tin. In one aspect, the alloy has a wt. % of tin in range of 0,001% and 50%, such as, for example 0.001%, 0,005%, 0.01%, 0.05%, 0.1%. 0.2%, 0.3%, 0.4%, 0.5%, 0.6%, 0.7%, 0.8%, 0.9%, 1%, 1.5%, 2%, 3%, 4%, 5%, 6%, 7%, 8%, 9%, 10%, 11%, 12%, 13%, 14%, 15%, 16%, 17%, 18%, 19%, 20%, 21%, 22%. 23%, 24%, 25%. 26%, 27%, 28%, 29%, 30%. 31%, 32%. 33%, 34%, 35%, 36%, 37%, 38%, 39%, 40%, 41%, 42%, 43%, 44%, 45%, 46%, 47%, 48%, 49%, or 50%.

In various aspects, a deformable conductive material can be a non-hazardous material. As used herein, the term “non-hazardous” can mean that a material is RoHS (Restriction of Hazardous Substances) complaint according to European Union Directive 2002/95/EC, Directive 2011/65/EU, and/or Directive 2015/863 (i.e. RoHS, RoHS 2, RoHS 3). For example, in some aspects, a non-hazardous material can include a wt. % of less than 0.01% Cadmium (Cd), less than 0.1% Lead (Pb), less than 0.1% Mercury (Hg), less than 0.1% Hexavalent Chromium (Cr VI), less than 0.1% Polybrominated Biphenyls (PBB), less than 0.1 Polybrominated Diphenyl Ethers (PBDE), less than 0.1% Bis(2-Ethylhexyl) phthalate (DEHP), less than 0.1% Benzyl butyl phthalate (BBF), less than 0.1% Dibutyl phthalate (DBP), and less than 0.1% Diisobutyl phthalate (DIBP).

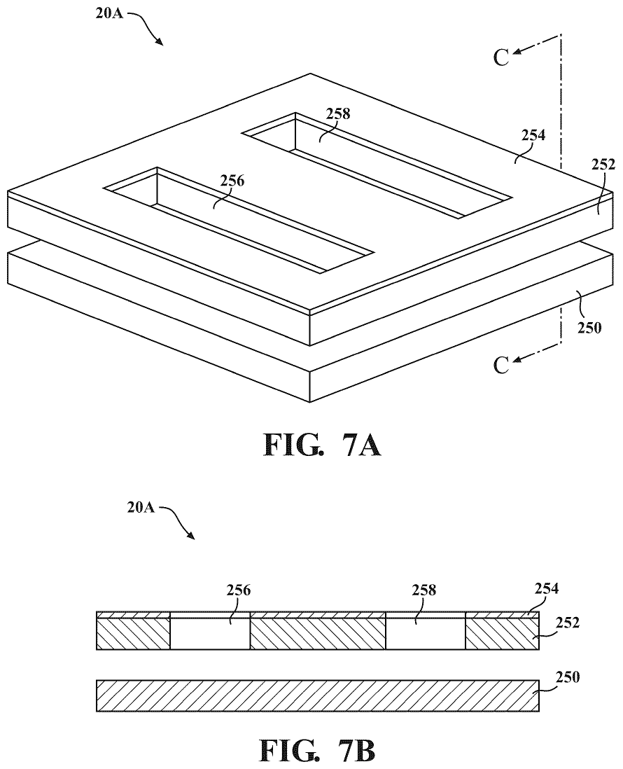

The deformable conductive materials disclosed herein can be efficient in the sense that they may be readily reclaimable and readily recyclable. In some aspects, the deformable conductive materials disclosed herein can be highly efficient. As used herein, a “highly efficient” circuit and/or method of circuit assembly may be “highly sustainable,” as disclosed in U.S. Provisional Patent Application No. 63/154,665, titled HIGHLY SUSTAINABLE CIRCUITS AND METHODS FOR MAKING THEM, filed Feb. 26, 2021, the disclosure of which is hereby incorporated by reference in its entirety. In other words, “high efficiency” may refer to a material and/or article of manufacture that is readily reclaimable and/or includes readily reclaimable components, requires relatively little energy and other resources to manufacture, is non-hazardous and/or includes non-hazardous components, does not cause toxic emissions when manufactured, and/or does not generate other waste when manufactured. In some aspects, a highly-efficient, deformable conductive material may be readily reclaimable; may be non-hazardous; may be manufactured while emitting substantially no VOCs; may be deposited while consuming relatively small amounts of energy; may be deposited in a single operation; or may be deposited, reclaimed, and recycled without consuming natural resources (e.g., water) and while producing substantially no waste; or a combination thereof. In some aspects, a highly-efficient circuit assembly may include a highly-efficient, deformable conductive material; may include one or more layers (e.g., substrate layers, stencil layers, insulation layers, encapsulation layers etc.) including a highly-efficient material; and/or may be made using the various manufacturing techniques described in detail below with respect to any of FIGS. 7A and 7B through 28.

However, according to other non-limiting aspects, a “highly efficient” circuit and/or method of circuit assembly can involve fewer materials, waste, and/or steps of manufacture. In other words, according to some non-limiting aspects, the circuits disclosed herein can include an enhanced efficiency because they can be produced from fewer layers. For example, a “highly efficient” circuit may include a substrate layer and an encapsulation layer and the deformable conductor can be deposited on the substrate layer without requiring an intermediate substrate layer in the final circuit assembly, as disclosed in further detail herein.

In various aspects, a deformable conductive material may exhibit adhesion to various layers of a circuit assembly and terminal/contacts of an electric component, as determined by the “Smear Test,” The Smear Test may be performed by smearing approximately 1 cm 3 of a deformable conductive material on a test coupon of the layer material or the terminal/contact material. The deformable conductive material is smeared with a cotton swab a Q-Tip™) across the test coupon, if the deformable conductive material coats the test coupon without void formation, then the deformable conductive material exhibits adhesion to the test coupon material. Conversely, if smearing the deformable conductive material to the test coupon causes the deformable conductive material to bead, thereby leaving voids on the test coupon, then the deformable conductive material does not exhibit adhesion. For example, some formulations of deformable conductive materials may have a surface tension that causes the deformable conductive material to bead. The Smear Test should be performed for all materials that have contact interfaces with the deformable conductive material to test for adhesion (e.g., terminals, channels, leads, contact point walls, etc.).

Referring again to FIG. 1, the circuit assembly 10 can include an electric component 104. The electric component 104 can be supported by the substrate 100 and can include one or more terminals 106, The one or more terminals 106 may be configured in various arrangements depending on a type of electrical component 104 that is used, as discussed in more detail below. Thus, the pattern of contact points 102 may be configured based on the number and arrangement of terminals 106 of the electric component 104 such that the pattern of contacts points 102 align with or otherwise correspond to the one or more terminals 106. According to the non-limiting aspect of FIG. 1, the one or more terminals 106 are shown with dashed lines (phantom view) as they are located on a face of the electric component 104 that is not viewable from the perspective shown in FIG. 1. The one or more terminals 106 of the electric component 104 may contact one or more corresponding portions of the pattern of contact points 102 to form one or more electrical connections between the electric component 104 and the pattern of contact points 102. The one or more terminals 106 may contact the one or more corresponding portions of the pattern of contact points 102, for example, as the electric component 104 is adhered to, attached to, brought in proximity to, or otherwise supported by the substrate 100, as shown by arrow 108. Therefore, various aspects of the circuit assembly 10 may enable the creation of electrical connections without soldering or other conventional processes for creating electrical connections.

In various aspects, the pattern of contact points 102 may be supported by the substrate 100, for example, by being formed directly on the surface of the substrate, by being recessed into the substrate 100, by being formed on another layer of material above the substrate 100, or in other ways. The electric component 104 may be supported by the substrate 100, for example, by being attached directly to the surface of the substrate 100, by being attached to another component that is supported by the substrate 100, for example, by being adhered to or otherwise supported by the pattern of contact points 102.

In various aspects, circuit assembly 10 can include a pattern of reusable conductive trace (not shown) formed from a deformable conductive material and supported by the substrate 100. In some aspects, the pattern of reusable conductive trace can be similar to the traces disclosed below. The pattern of reusable conductive trace may be interconnected with the pattern of contact points 102. In one aspect, the pattern of contact points 102 and the reusable conductive trace may be formed from the same deformable conductive material.

The various components of FIG. 1 may include one or more of a wide variety of readily reclaimable and/or readily recyclable materials. In various aspects, the substrate 100 can include, for example, thermosetting plastic materials; thermoplastic materials (i.e. thermoplastic polymers), such as, for example, thermoplastic polyurethane (TPU), high density polyethylene (HDPE), polyethylene terephthalate (PET), polyvinyl chloride (PVC), low density polyethylene (LDPE), polypropylene (PP), polystyrene (PS); fabrics; wood; paper; or other insulating materials; or a combination thereof.

Referring still to FIG. 1, the electric component 104 can be any electrical, electronic, electromechanical, and/or electric device or feature, such as, for example, an integrated circuit, semiconductors, transistor, diode, LED, capacitor, resistor, inductor, switch, terminal, connector, display, sensor, printed circuit board, or other device or feature. In some aspects, the electric component 104 may include a bare component. In some aspects, the electrical component 104 may be partially or fully enclosed in various types of packages. In some aspects, where the electrical component 104 includes an integrated circuit and/or a semiconductor, a wide range of package types may be used, as described in detail below. For example, the electrical component 104 may include an integrated circuits in the form of a bare die. As another example, the electrical component may include a die mounted to a substrate but not fully enclosed in a package, such as chip-scale device.

Still referring to FIG. 1, the circuit assembly 10 can be a highly efficient circuit assembly, A highly efficient circuit assembly 10 can include a substrate layer 100 including a readily reclaimable material, such as, for example, a thermoplastic polymer or one or more of the various substrate materials disclosed above. A highly efficient circuit assembly 10 can include contact points 102 including a readily reclaimable, deformable conductive material (e.g., a highly efficient deformable conductive material), such as, for example, one or more of the various deformable conductive materials disclosed above. In various aspect, the circuit assembly 10 can be made and/or processed using the various manufacturing, reclamation, and recycling techniques described in detail below with respect to any of FIGS. 7A and 7B through 19. Thus, a highly efficient circuit assembly 10 can include components that may be formed and/or deposited, reclaimed, and recycled without consuming natural resources (e.g., water) and/or while producing substantially no waste.

Having described a general implementation of the circuit assembly 10, which, in some aspects, can be a highly efficient circuit 10, the disclosure turns to various other circuit assemblies. Any of the aspects of circuit assembly 10 described above (e.g., the substrate layer 100, the pattern of contact points, 102, the electrical component 104, the one or more terminals 106, etc.) may be applied to any of the various other circuit assemblies described below. Likewise, any of the aspects of the various other circuit assemblies described below may be applied to the circuit assembly 10. Thus, any of the circuit assemblies described below can be a highly efficient circuit assembly.

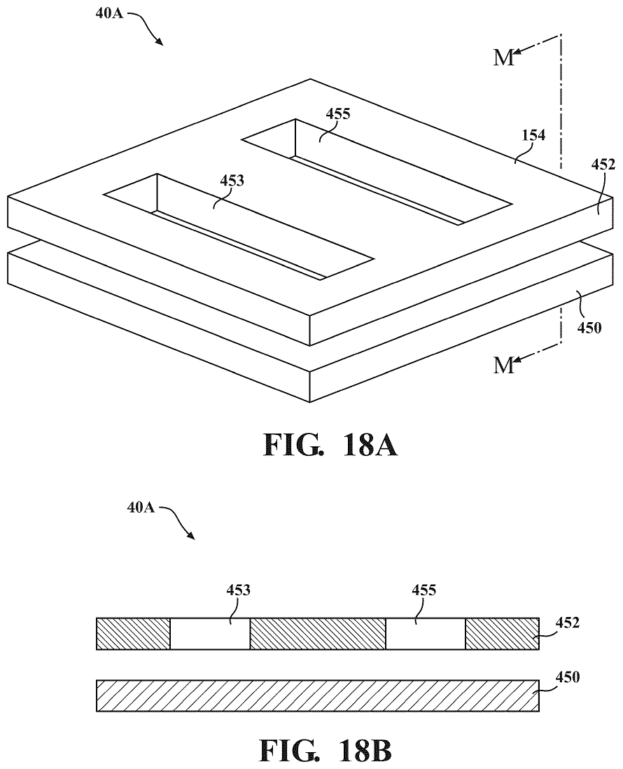

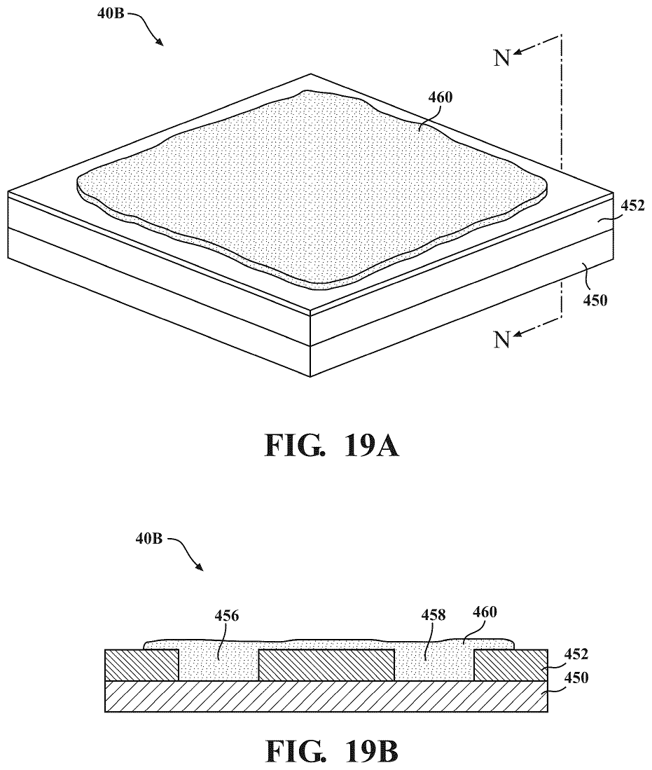

Referring now to FIG. 2, an exploded partial perspective view of a circuit assembly 12 is depicted in accordance with at least one non-limiting aspect of the present disclosure. According to the non-limiting aspect of FIG. 2, circuit assembly 12 can include an integrated circuit (IC) 116 configured in a surface-mount package having terminals in the form of leads 118A-118F (referred to collectively as leads 118; leads 118E-118F not shown). The circuit assembly 12 can include a substrate layer 110 including a pattern of contact points 112A-112F (referred to collectively as contact points 112) including a deformable conductive material and arranged to correspond to the footprint of the leads 118 of IC 116. In various aspects, the contact points 112 can be formed in the shape of solder pads which would conventionally be used to make electrical connections between the IC 116 and a printed circuit board. Reusable conductive traces 114A-114F (referred to collectively as reusable conductive traces 114), which may also be made from a deformable conductive material, are respectively connected to the contact points 112A-112F and can extend to the edges of the substrate layer 110. As will be described in further detail herein, the pattern of contact points 112 and/or reusable conductive traces 114 can be particularly configured for reuse via methods 1000, 2000 of FIGS. 18 and 19. The reusable traces 114 may be used, for example, to connect the integrated circuit 116 to other electrical components, circuitry, terminals, etc. The leads 118A-118F contact the corresponding contact points 112A-112F, respectively, when the integrated circuit 116 is adhered to, attached to, brought in proximity to, placed onto, or otherwise supported by the substrate 110, as shown by arrow 120. In the non-limiting aspect of FIG. 2, the contact points 112 and reusable traces 114 are formed on a surface of, and protrude above, the substrate layer 110 by, for example, flexographic printing, block printing, jet printing, 3-D printing, stenciling, masked spraying, extruding, rolling, brushing, screen printing, pattern deposition, or any other suitable technique.

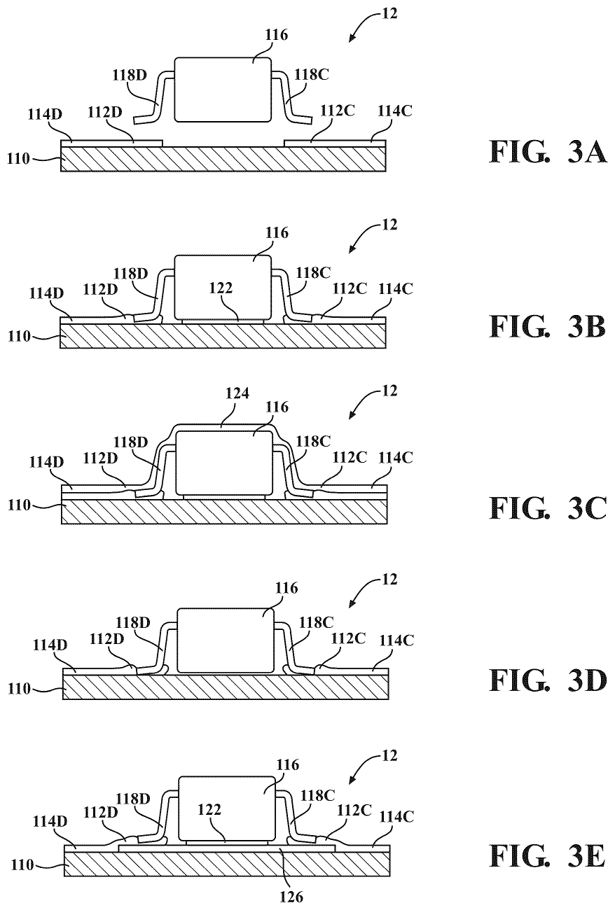

FIGS. 3A-3E are cross-sectional views taken through line A-A of FIG. 2 illustrating exemplary aspects of circuit assembly 12, in accordance with non-limiting aspects of the present disclosure. Although specific contact points (i.e. contact points 1120, 112D), leads (i.e., leads 1140, 114D), and terminals (i.e., terminals 118C, 118D) are depicted in FIGS. 3A-3E, the various details presented can apply to any instance of the contact points, leads, and/or terminals. Thus, these components are referred to as contact points 112, leads 114, and terminals 118 below.

Referring now to FIG. 3A, circuit assembly 12 is illustrated prior to bringing the IC 116 proximate to the substrate layer 110, in accordance with at least one non-limiting aspect of the present disclosure.

Referring now to FIG. 3B, circuit assembly 12 is illustrated with the IC 116 supported by the substrate layer 110 and forming ohmic contacts between the leads 118 and contact points 112, in accordance with at least one non-limiting aspect of the present disclosure. The IC 116 is secured to the substrate layer 110 by a layer of adhesive 122. In the non-limiting aspect of FIG. 3B, the leads 118 have displaced some of the deformable conductive material of the contact points 112. The displacement of the deformable conductive material by the leads 118 may cause the deformable conductive material to conform to the shape of the leads 118 and may provide additional contact surface area and improved electrical connection between the contact points 112 and the IC 116.

Referring now to FIG. 3C, circuit assembly 12 is illustrated with an encapsulant 124 covering all or a portion of the integrated circuit 116, leads 118, contact points 112, or reusable traces 114, or any combination thereof, in accordance with at least one non-limiting aspect of the present disclosure. The encapsulant 124 may also fill the space between the integrated circuit 116, leads 118, and substrate layer 110. The encapsulant 124 can include silicone-based materials, such as, for example, polydimethylsiloxanes (PDMS), urethanes, epoxies, polyesters, polyamides, varnishes, and any other materials that may provide a protective coating and/or help to hold circuit assembly 12 together. In various aspects, the encapsulant 124 can be a thermoplastic polymer (e.g., a polymer material that is similar to or the same as substrate layer 110). Thus, the encapsulant 124 can include a highly efficient material.

Referring now to FIG. 3D, circuit assembly 12 is illustrated with IC 116 directly contacting the substrate layer 110, in accordance with at least one non-limiting aspect of the present disclosure. In some aspects, substrate layer 110 may include an inherently adhesive or sticky material having a tacky characteristic sufficient to secure IC 116 to the substrate layer 110. In some aspects, the encapsulant 124 described above with respect to FIG. 30 may secure the IC 116 directly to the substrate layer 110 without need for the adhesive 122. In one aspects, configuring circuit assembly 12 such that the IC 116 directly contacts the substrate layer 110 may cause the leads 118 to press further into the contact points 112 compared to the non-limiting aspects of circuitry assembly 12 where the adhesive 122 is used.

Referring now to FIG. 3E, circuit assembly 12 is illustrated with a layer 126 of material attached to a surface of the substrate layer 110 and located between the pattern of contact points 112 and the substrate layer 110. The layer 126 may perform various functions. For example, the substrate layer 110 may be made from a flexible or stretchable material whereas the layer 126 may be made from a relatively more rigid or less stretchable material to prevent flexing or stretching of the region of the substrate 110 proximate to the IC 116 or other electric component. Thus, the layer 126 can serve to prevent connection failures between terminals 118 of the integrated circuit 116 and the contact points 112 that may otherwise occur due to the flexing or stretching of the substrate 110. As another example, the layer 126 may perform a heat sinking or heat dissipating function for the IC 116 or other electric component. As yet another example, the layer 126 may have an adhesive or tacky characteristic that is greater than that of the substrate layer 110. Thus, the layer 126 may be used with or without the adhesive 122 and may serve to secure the IC 116 or other electric component to the substrate layer 110. In some aspects, a layer 126 may additionally or alternatively be located on a surface of the substrate layer 110 that is opposite to the surface of the substrate layer 110 that the IC 116 is attached to. In some aspects, a layer 126 may additionally or alternatively be located within the substrate. In some aspects, a layer 126 may additionally or alternatively be located in other locations of circuit assembly 12. The layer 126 may be formed as a continuous sheet of material, or it may be patterned, for example, with openings for any or all the contact points 112, reusable traces 114, integrated circuit 116, or other components. The layer 126 can include materials such as, for example, TPU, fiberglass, PET, polyimide (PI), or a B-stage resin film. In various aspects, the layer 126 can include a thermoplastic polymer (e.g., a polymer material that is like or the same as substrate layer 110). Thus, the layer 126 can include a highly efficient material.

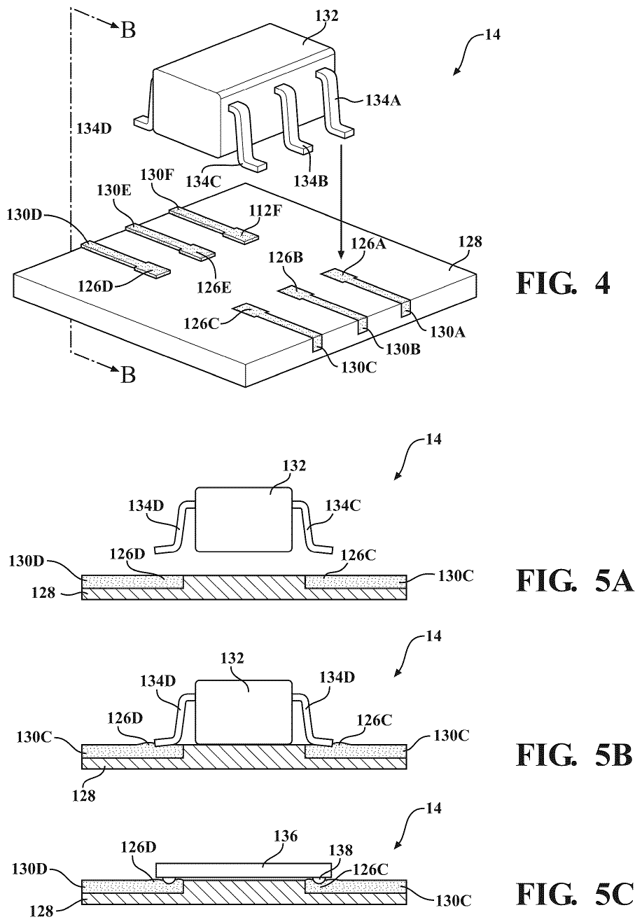

Referring now to FIG. 4, an exploded partial perspective view of a circuit assembly 14 is depicted in accordance with at least one non-limiting aspect of the present disclosure. Circuit assembly 14 can include a substrate layer 128, a pattern of contact points 126A-F (collectively contact points 126), reusable traces 130A-F (collectively reusable traces 130), and an IC 132 including terminals 134A-134F (collectively terminals 134). Circuit assembly 14 may be similar to circuit 12 of FIG. 2, except that the contact points 126 and traces 130 of circuit assembly 14 may be formed by recesses in the substrate layer 128 that are partially or fully filled with a deformable conductive material. The contact points 126 recesses in the substrate layer 128 may be formed by removing portions of the substrate layer 128 sheet material by drilling, routing, etching, cutting or any other method of removing material with mechanical optical (e.g., laser), chemical, electrical, ultrasound, or other apparatus or combination thereof. Alternatively or additionally, the substrate layer 128 may be formed with the contact points 126 recesses via a molding, casting, 3-D printing, or other formation process. The deformable conductive material may be deposited in the contact points 126 recesses through any of the processes mentioned above including printing, stenciling, spraying, rolling, brushing, and any other technique for depositing material in the recesses. Additionally, the contact points 126 recesses may be overfilled with deformable conductive material and then any suitable technique including scraping, rolling, brushing, etc. may be used to remove excess material so that it is flush with, or protruding beyond (i.e. overfilling) or recessed within (i.e. underfilling) the surrounding surface of the substrate layer 128, as described in more detail below,

FIGS. 5A-50 are cross-sectional views taken through line B-B in FIG. 4 illustrating exemplary aspects of circuit assembly 14, in accordance with non-limiting aspects of the present disclosure. Although specific contact points (i.e., contact points 1260, 126D), leads (i.e., leads 1300, 130D), and terminals (i.e., terminals 1340, 134D) are depicted in FIGS. 5A-50, as the case may be, the various details presented can apply to any instance of the contact points, leads, and/or terminals. Thus, these components are referred to as contact points 126, leads 130, and terminals 134 below.

Referring now to FIG. 5A, circuit assembly 14 is illustrated prior to bringing the IC 132 proximate to the substrate layer 128, in accordance with at least one non-limiting aspect of the present disclosure.

Referring now to FIG. 5B, circuit assembly 14 is illustrated with the IC 132 supported by the substrate layer 128 and forming ohmic contacts between the leads 134 and contact points 126, in accordance with at least one non-limiting aspect of the present disclosure. In some aspects, the IC 132 is mounted directly to the substrate layer 128 which may, for example, include a self-adhesive surface, as explained above with respect to substrate layer 110 in FIG. 3D. Alternatively, the IC 132 may be attached to the substrate using adhesives or any other suitable technique, such as, for example, those described above with respect to FIGS. 3B-3E. In the non-limiting aspect of FIG. 5B, the leads 134 protrude into the contact points 126 and displace some of the deformable conductive material. The displacement of the deformable conductive material by the leads 134 may cause the deformable conductive material to conform to the shape of the leads 134 and may provide additional contact surface area and improved electrical connections between contact points 126 and the IC 132.

In the non-limiting aspects of FIGS. 2, 3A-3E, 4, and 5A-58, the respective ICs are illustrated as surface-mount packages, such as, for example, a SOT23-6 (small outline transistor, six lead) package. Of course, any other types of IC packages and electronic components may be used with the circuit assemblies disclosed herein (e.g., as disclosed above with respect to electrical component 104 of FIG. 1). For example, referring now to FIG. 5C, circuit assembly 14 is illustrated with a chip-scale package 136 as the integrated circuit (in place of IC 132), in accordance with at least one non-limiting aspect of the present disclosure. The chip-scale package 136 includes solder bumps 138, Similar to leads 134, the solder bumps 138 can form ohmic contacts with contact points 126.

In various aspects, leadless chip carriers may be used with the circuit assemblies disclosed herein. Leadless chip carriers can have terminals with flat lead surfaces that provide a good interface to any of the disclosed contact points without disrupting the patterns of deformable conductive material. In other aspects, packages with protruding solder structures such as ball grid arrays (BGAs) and wafer-level chip-scale packaging (WL-CSP), such as chip-scale package 136 shown in FIG. 5C, and packages with slightly protruding leads such as leaded chip carriers may be used with the circuit assemblies disclosed herein. Packages with protruding solder structures or leads may be used because the deformable conductive materials can allow for the protruding solder structures or leads to sink into the contact points and create reliable ohmic connections without displacing so much of the deformable conductive material that it disrupts the patterns.

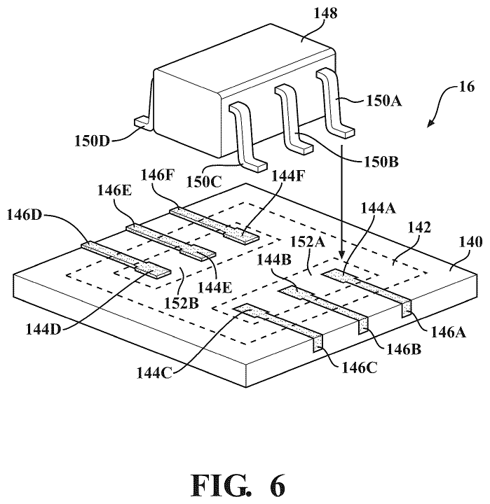

Referring now to FIG. 6, an exploded partial perspective view of a circuit assembly 16 is depicted in accordance with at least one non-limiting aspect of the present disclosure, Circuit assembly 16 can include a substrate layer 140, a pattern of contact points 144A-F (collectively contact points 144), reusable traces 146A-F (collectively reusable traces 146), and an IC 148 including terminals 150A-150F (collectively terminals 150), Circuit assembly 16 may be similar to circuit assembly 14 of FIG. 4, except that a layer 142 of material is attached to a surface of the substrate layer 140 after formation of the pattern of contact points 144 and reusable traces 146, but before attachment of the integrated circuit 148, The layer 142 may be similar, for example, to the layer 126 in the non-limiting aspect of FIG. 3E. According to the non-limiting aspect of FIG. 6, the layer 142 includes openings 152A and 152B for the contact points 144. However, the layer 142 can include any number and pattern of openings to expose the various patterns of contact points 144 that may be implemented. As used herein “a pattern of openings” can include at least one specifically configured opening.

In addition to packaged integrated circuits and other devices, bare integrated circuit dies, and other components may be used with the circuit assemblies disclosed herein. For example, an IC die including bonding or contact pads may be attached to a substrate layer having a flush or protruding pattern of contact points that corresponds to the pattern of bonding or contact pads on the die. In some aspects, the bare integrated circuits dies may be mounted with the bonding or contact pads facing the surface of the substrate including the contact points (e.g., the die may be mounted upside down). This mounting can result in the deformable conductive material of the contact points forming ohmic connections with the bonding or contact pads.

Although the deformable conductive material is generally shown as being flush with the surface of the substrate in circuit assemblies 14 and 16 of FIGS. 4, 5A-5C, and 6, the deformable conductive material may additionally or alternatively be formed shy of (i.e., recessed within) or proud of (i.e., protruding beyond) the surface of the substrate layer 128, 140. In some aspects, the deformable conductive material may be formed shy of the surface of the substrate layer 128, 140, for example, by only partially filling some or all the recesses of the contact points 126, 144 with material, or by removing some material by scraping, brushing, gouging, etching, evaporating, etc. In some aspects, the deformable conductive material may be formed proud of the surface of the substrate layer 128 by pattern depositing, stenciling, various forms of printing, etc. In some non-limiting aspects, the deformable conductive material may be formed proud of the surface of the substrate layer 126, 144 by using a release layer with a pattern that matches the pattern of the recesses of the contact points 126, 144. The release layer may be positioned over the substrate layer 128, 140 and the pattern of recesses may be over-filled and then scraped flush with the top surface of the release layer. The release layer may then be removed to leave protruding deformable conductive material in a manner described below.

FIGS. 2, 3A-3E, 4, 5A-5C, and 6 generally show the contact points and reusable traces of circuit assemblies 12, 14, 16 on the surface of, or extending part way into, the substrate layer. In various aspects of the present disclosure, the circuit assemblies described herein can be configured such that some or all the contact points and/or reusable traces extend through the entire thickness of a substrate layer. For example, contact points may be implemented as vias through the substrate layer, which, in turn, may serve as a stack layer, as described below.

Having described a general implementation of the circuit assemblies 10, 12, 14, and 16 which, in some aspects, can be highly efficient circuits, the disclosure turns to various other circuit assemblies and methods for their manufacture. The various other circuit assemblies described below can have stacked layers and may include patterns of deformable conductive materials formed in and/or between the stacked layers. Any of the aspects of circuit assemblies 10, 12, 14, and 16 described above (e.g., the substrate layer, the pattern of contact points, the electrical component (e.g., the IC), the one or more terminals, etc.) may be applied to any of the various other circuit assemblies described below. Likewise, any of the aspects of the various other circuit assemblies, and the methods for their manufacture, described below, may be applied to circuit assemblies 10, 12, 14, and 16 above.

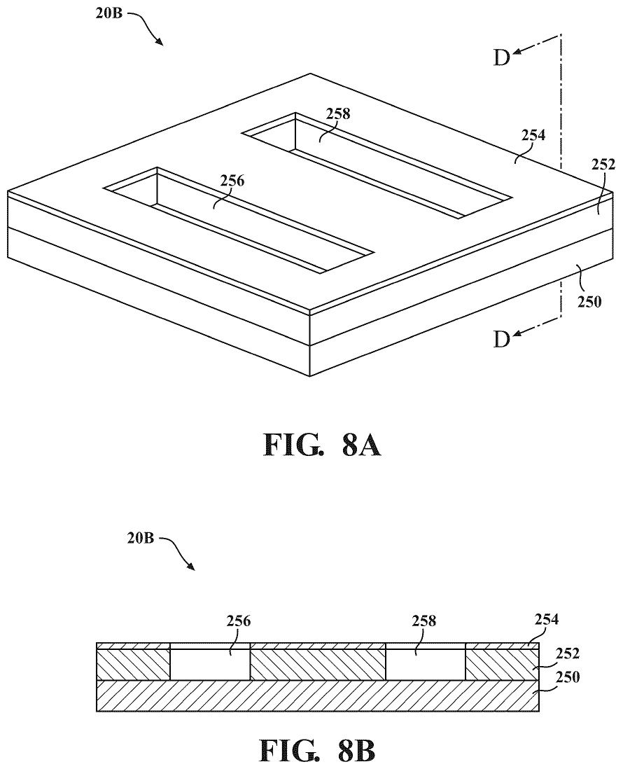

FIGS. 7A and 7B through 15A and 15B illustrate various intermediate and final circuit assemblies that may include a stencil layer having a pattern of deformable conductive material formed therein, in accordance with non-limiting aspects of the present disclosure. In some aspects, FIGS. 7A and 7B through 15A and 15B can correspond to various steps for methods of manufacturing the intermediate and final circuit assemblies. FIGS. 73, 8B, 98, 10B, 118, 128, 13B, 143, and 153 are cross-sectional views of FIGS. 7A, 8A, 9A, 10A, 11A, 12A, 13A, 14A, and 15A, respectively.

Referring now to FIG. 7A, a perspective view of a circuit assembly 20A is illustrated prior to stacking a substrate layer 250 with a first stacked layer 252, in accordance with at least one non-limiting aspect of the present disclosure. In the non-limiting aspect of FIG. 7, the first stacked layer 252 is shown as a stencil layer. In other aspects, the first stacked layer 252 can be an insulation layer. In some aspects, circuit assembly 20A can include a release layer 254 attached to the first stacked layer 252. FIG. 78 is a cross-sectional view taken through line C-C of FIG. 7A. FIGS. 7A and 7B can correspond to beginning or intermediate step(s) for manufacturing a highly efficient circuit assembly. The substrate layer 250 and first stacked layer 252, as well as any additional stacked layers shown in FIGS. 8A and 8B through 15A and 153 (e.g., layers 270, 276, 282, etc.), may be fabricated from materials disclosed above with respect to the substrate layer 100 of FIG. 1. For example, the substrate layer 250 and first stacked layer 252 may be fabricated from a readily recyclable polymer material such as TPU. The substrate layer 250 may generally be an uninterrupted sheet of material, whereas the first stacked layer 252 and the release layer 254 may include a pattern of one or more passages (e.g., openings; e.g., channels 256 and 258) configured to house a deformable conductive material. In various aspects, the passages 256, 258 can be channels cut through the entire thicknesses of a sheet of material used to create a mask or stencil, thus creating the first stacked layer 252 (e.g. a stencil layer). The release layer 254, may be thinner than the first stacked layer 252 and may be stacked onto the first stacked layer 252.

In various aspects, release layer(s), such as, for example, release layer 254, may be applied and removed during production of the various circuit assemblies disclosed herein. In some aspects, release layer(s) may be the only significant “waste” product generated during the manufacture of the circuit assembly. As such, preference may be given to circuit assembly designs and materials that do not include a release layer.

However, in various aspects, it may be desirable to produce the various circuit assemblies disclosed herein using a release layer, for example, to achieve the contact point configurations described below. Where a release layer is used during production, the release layer may be formed from a readily recyclable material, such as, siliconized or non-siliconized PET film, or siliconized or non-siliconized paper-based release film. Methods for recycling these release layers are described in U.S. Pat. Publication No. 8,842,840, titled PROCESS FOR RECYCLING WASTE FILM AND PRODUCT MADE THEREFROM, published Sep. 30, 2014, the disclosure of which is hereby incorporated by reference in its entirety. Methods for these recycling process have also been commercialized, for example, by Mitsubishi under the name Reprocess™. Thus, a circuit assembly including a readily recyclable release liner and/or manufactured using a readily recyclable release liner may be a highly efficient circuit assembly.

Referring again to FIGS. 7A and 7B, the passages 256, 258 may be formed in the first stacked layer 252 and, if applicable, the release layer 254 using subtractive techniques, such as, for example, laser cutting, drilling, routing, die cutting, water-jet cutting, etc. In other aspects, the first stacked layer 252 and/or the release layer 254, and thus passages 256, 258, may be formed using an additive manufacturing technique, such as, for example, 3-D printing, pattern deposition, molding (injection, press) etc. These techniques may be similarly applied to form the additional stacked layers disclosed below with respect to FIGS. 8A and 88 through 15A and 158 (e.g., stacked layers 270, 276, 282, etc.).

In various aspects, the technique used to form layers of the circuit assemblies disclosed herein may produce scrap (e.g., due to cutting passages etc.). The amount of scrap produced may be relatively small because passage features can be small and thus only small amounts of material need to be removed (e.g., passage features may generally have micron scale widths and/or depths, such as widths and/or depths in a range of 80-400 microns). Nevertheless, because the layers of the circuit assemblies disclosed herein can include readily reclaimable and readily recyclable materials, scrap produced during forming the layers may be collected, re-processed, and used in the manufacturing of subsequent layers and/or circuit assemblies.

Referring now to FIG. 8A, a perspective view of a circuit assembly 208 is illustrated after stacking the substrate layer 250 with the first stacked layer 252, in accordance with at least one non-limiting aspect of the present disclosure. FIG. 88 is a cross-sectional view taken through line D-D of FIG. 8A. FIGS. 8A and 8B can correspond to a step or steps for manufacturing a highly efficient circuit assembly. Prior to subsequent manufacturing steps, the substrate layer 250 and first stacked layer 252 may be bonded, fused or cured together, or otherwise attached to each other with any suitable processes and/or materials. For example, in some aspects, the substrate layer 250 and the first stacked layer 252 can be indexed in the stacked position (e.g., using indexing pins). In some aspects, the substrate layer 250 and first stacked layer 252 can be fabricated from TPU or other thermoplastic materials and may be bonded together with heat and pressure. In some aspects, the substrate layer 250 and/or the first stacked layer 252 can be fabricated from an inherently tacky material such as, for example, a b-stage resin material or an aliphatic TPU film (e.g. Huntsman Krystalflex™), In some aspects, the substrate layer 250 and the first stacked layer 252 can be bonded together by self-adhesion and pressure. In some aspects, substrate layer 250 and/or the first stacked layer 252 can be fabricated from a UV-curable material and exposed to a UV light source after stacking. Bonding of the substrate layer 250 and the first stacked layer 252 during stacking may cause the channels 256 and 258 to be sealed at the interface between the substrate layer 250 and the first stacked layer 252 and ensure there is no leakage when depositing the deformable conductor material, as described below. Leakage of the deformable conductor may additionally or alternatively be prevented in other ways such as, for example, by configuring the deformable conductive material formulation to prevent leakage (e.g., adjusting the rheological parameters of the deformable conductive material); by using tooling (e.g., clamping the layers and/or using pins); and adjusting operation parameters used during manufacturing of the circuit assembly (e.g., adjusting the application pressure of a wiping operation).

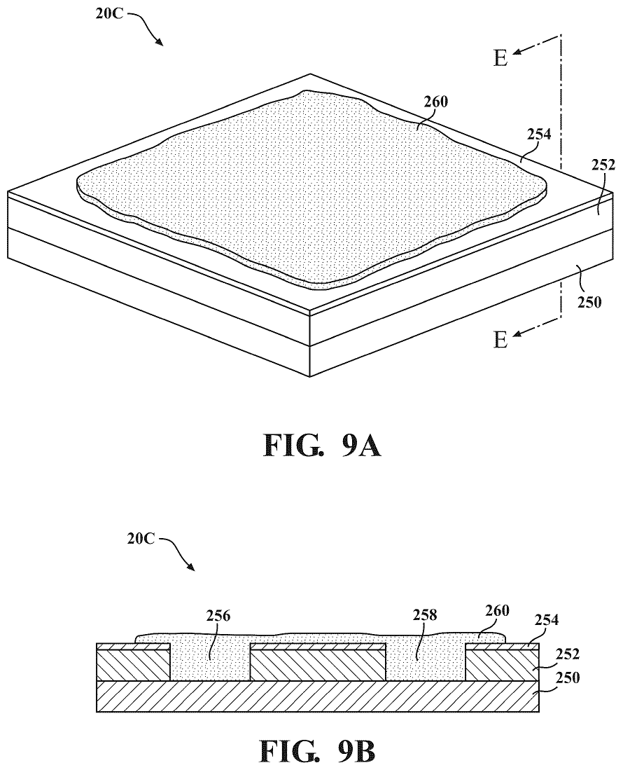

Referring now to FIG. 9A, a perspective view of a circuit assembly 20C is illustrated after over-filling the channels 256 and 258 of the first stacked layer 252 with a deformable conductive material 260. FIG. 9B is a cross-sectional view taken through line B-E of FIG. 9A. FIGS. 9A and 9B can correspond to a step or steps for manufacturing a highly efficient circuit assembly. The deformable conductive material 260 may include any of the deformable conductive materials disclosed above with respect to FIG. 1. In various aspects, the deformable conductive material 260 can be readily reclaimable and/or highly efficient, thus enabling circuit assembly 20 to be highly efficient circuit layup. For example, the deformable conductive material 260 can include the conductive gel (e.g., a gallium indium alloy) disclosed above. Overfilling the channels 256, 258 with the disposable conductive material 260 may be performed using any suitable technique such as, for example, extruding, rolling, swabbing, spraying, printing, brushing, deposition, etc. In some aspects, the channels 256, 258 may be over-filled with the deformable conductive material 260 using a cotton swab. Using the cotton swab can include working the deformable conductive material 260 completely into the channels 256, 258.

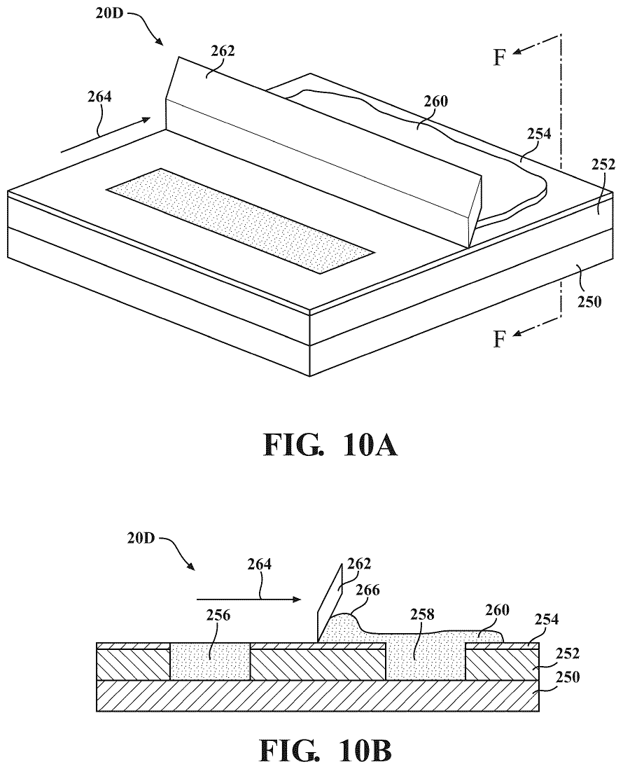

Referring now to FIGS. 10A, a perspective view of circuit assembly 20D is illustrated during wiping of excess deformable conductive material 260, according to at least one non-limiting aspect of the present disclosure. FIG. 10B is a cross-sectional view taken through line F-F of FIG. 10A. FIGS. 10A and 10B can correspond to a step or steps for manufacturing a highly efficient circuit assembly. After the deformable conductive material 260 is deposited onto circuit assembly 20 (e.g., overfilled into channels 256, 258), excess deformable conductive material 260 can be wiped from the surface of the first stacked layer 252, or, as shown in the non-limiting aspect of FIGS. 10A and 10B, the release layer 254. The wiping can be performed using a wiping tool 262 by wiping in the direction shown by arrow 264. Wiping tool 262 can be a squeegee including a blade having a resilient characteristic and configured to cause the application of a downward pressure to the surface of the first stacked layer 252 and/or the release layer 254 while being translated over the surface of the layer, as the case may be. This wiping operation can cause excess deformable conductive material 260 to form a mound 266 in front of the tool 262 which may help to fill any under-filled areas of the channels 256 and 258. Excess deformable conductive material 260 may be collected and used to fill channels or form reusable traces and/or contact points in another circuit assembly. The various deposition methods described herein can use a singular operation for applying the deformable conductive material 260 to each layer of a circuit assembly. In some aspects, no further operations are necessary to produce functional reusable traces and/or contact points in a circuit assembly.

To assess the viability of collecting and reusing a deformable conductive material in a production environment, the inventors collected deformable conductive material reclaimed from several deposition and wiping operations (i.e., the same bulk material was reclaimed and reused over several circuit assembly deposition operations) and tested for performance. Reclaimed excess material from previous operations was experimentally found to offer substantially indistinguishable performance compared to virgin stock, as shown in Examples 1 and 2 below. Thus, compared to conventional circuit boards and related methods, the various circuit assemblies and related methods disclosed herein can reduce or eliminate waste production and/or reduce or eliminate resource consumption that results from the deposition of conductive materials. For example, as described in detail above, conventional methods of producing FR4/copper circuit boards often involve various resource-consuming curing, etching, and stripping steps that generate waste materials such as the etched excess copper conductor and other spent materials. Moreover, epoxy-based conductive adhesives used to replace soldering are often wasted due to their decreased ability to be reused after curing. Conversely, in various aspects, the deformable conductive material described herein can be deposited onto a circuit assembly and the excess can be collected and reused without consuming resources (e.g., water), without expending energy (e.g., without consuming electricity, without applying heat, without having to solder, etc.), without wasting the deformable conductive material (e.g., because it can be collected and reused), without generating other waste products (e.g. without using cleaning solvents, without chemical etching, etc.), and/or without producing hazardous byproducts (e.g., because the deformable conductive material can be non-hazardous).

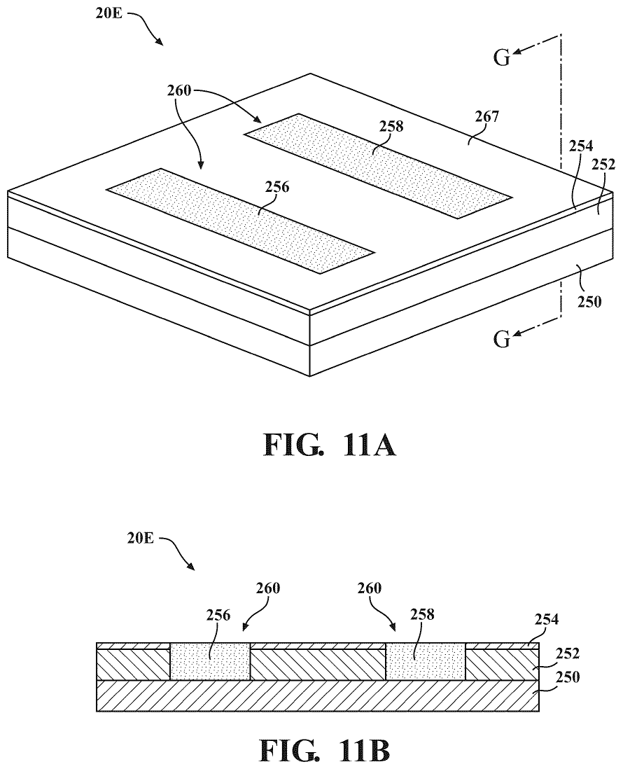

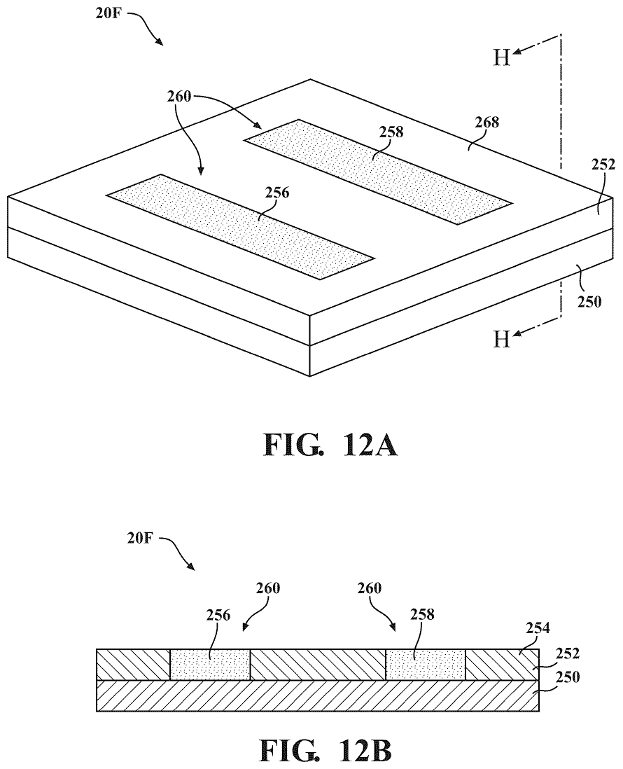

Referring now to FIG. 11A, a perspective view of circuit assembly 20E is illustrated with the deformable conductive material 260 being generally flush with a surface 267 of the release layer 254, and with all or most of the excess deformable conductive material 260 removed, in accordance with at least one non-limiting aspect of the present disclosure. FIG. 11B is a cross-sectional view taken through line G-G of FIG. 11A. FIGS. 11A and 11B can correspond to a step or steps for manufacturing a highly efficient circuit assembly that occur after a deposition step (e.g., overfilling and/or wiping step). Depending on the technique used to remove excess material, thin patches of deformable conductive material may remain on the surface 267 of the release layer 254. Thus, the release layer 254 may be removed, for example, by peeling the release layer 254 off of the circuit assembly 20E to leave a clean top surface 268 on the first stacked layer 252 as shown in FIGS. 12A and 12B. The removed release layer 254 may be collected and reprocessed to form new release layers, or other goods such as plastic bottles and the like.

Referring now to FIG. 12A, a perspective view of circuit assembly 20F is illustrated with the deformable conductive material 260 being generally flush with a surface 268 of the first stacked layer 252, and with all or most of the excess deformable conductive material 260 removed, in accordance with at least one non-limiting aspect of the present disclosure. FIG. 12B is a cross-sectional view taken through line H-H of FIG. 12A. The deformable conductive material 260 in channels 256 and 258 is shown as generally flush with the surface 268. This may be accomplished, for example, by not using a release layer, or by using a release liner 254 that is thin enough (e.g., in the range of 1-10 microns, 10-100 microns, or 1-10 thousandths of an inch thick) such that, after its removal, the remaining deformable conductive material 260 is effectively flush with the surface 268. Accordingly, in some aspects, the thickness of the release layer 254 may be exaggerated in the views of FIGS. 7A and 7B through 11A and 11B. In various aspects, if even a small amount of deformable conductive material 260 protrusion needs to be avoided, then a small protrusion of the deformable conductive material 260 may be removed from the channels 256 and 258 by wiping, scraping, brushing, etc. after removal of the release layer 254, thereby leaving the deformable conductive material 260 flush with the surface 268 of the first stacked layer 252. Thus, in some aspects, where the release layer 254 is used, FIGS. 12A and 12B can correspond to a step or steps for manufacturing a highly efficient circuit assembly that occur after removing the release layer 254. And in some aspects, where a release layer is not used, FIGS. 12A and 12B can correspond to a step or steps for manufacturing a highly efficient circuit assembly that occurs after a deposition step (e.g., overfilling and/or wiping step).

In various aspects, the deformable conductive material 260 can remain slightly proud of the surface 168. Thus, in one aspect, the thickness of the release layer 254 may purposely be set to a value that may cause the deformable conductive material 260 to protrude above the top surface 268 of the first stacked layer 252 by a predetermined amount.

The circuit assembly 20F of FIGS. 12A and 12B can have utility as fabricated, or it can serve as a base for additional layers. For example, as fabricated, circuit assembly 20F can include pattern of contact points (e.g., contact points 102 of FIG. 1) to engage the terminals (e.g., terminals 106 of FIG. 1) of an electric device (e.g., electrical component 104 of FIG. 1) that may be attached to, adhered to, mounted on, or otherwise supported by, the first stacked layer 252, similar to circuit assemblies 10, 12, 14, and 16 described above with respect to FIGS. 1 through 6. In one aspect, in such an application, the deformable conductive material 260 can protrude above the top surface 268 of the first stencil layer 252. This protrusion may allow for deformable conductive material 260 to better engage the terminals of the electric device. The configuration of the channels 256, 258 may be modified to include different numbers, sizes, shapes, etc. of conductive passageways. Thus, the channels 256, 258 including the deformable conductive material 260 can function as contact points and/or reusable traces (e.g., the various contact points and reusable traces disclosed above with respect to FIGS. 1-6).

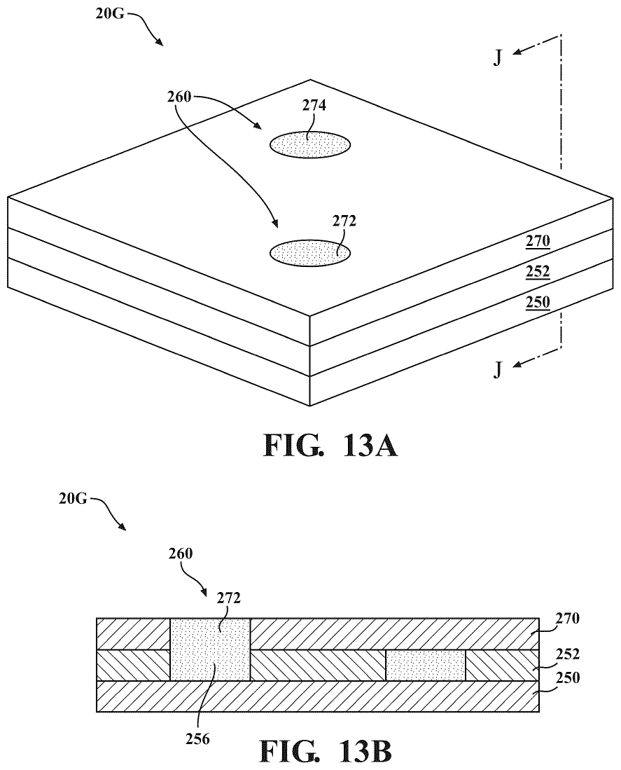

As another example, as fabricated circuit assembly 20F can be used as a circuit element itself. For example, one or more channels 256, 258 filled with deformable conductive material 260 may function as a transmission line, such as, for example, a strip line or as a circuit capacitor. In such an implementation, an insulation layer (e.g., the second stacked layer 270 of FIGS. 13A and 136) may be stacked on top of the first stacked layer 252 to enclose and protect the deformable conductive material 260.

In various aspects, circuit assembly 20F can include additional layers to create a stacked circuit assembly. For example, referring now to FIG. 13A, a circuit assembly 20G is illustrated with a second stacked layer 270 stacked on the first stacked layer 252, in accordance with at least one non-limiting aspect of the present disclosure. FIG. 13B is a cross-sectional view taken through line J-J of FIG. 13A. FIGS. 13A and 13B can correspond to a step or steps for manufacturing a highly efficient circuit assembly that occurs after a stacking step (e.g., after stacking the second stacked layer 270 on the first staked layer 252). The second stacked layer 270 may be an insulation layer or a stencil layer. In the non-limiting aspect of FIGS. 13A and 13B, the second stacked layer 270 functions as an insulation layer, and covers at least a portion of the pattern of passages of the first stacked layer 252 (e.g., covers at least a portion of channels 256, 258). The second stacked layer 270 can include a pattern of passages. The pattern of passages can be, for example, vias 272, 274 that respectively align with a portion of reusable traces formed by channels 256, 258 of the first stacked layer 252. The second stacked layer 270, vias 272, 274, and deformable conductive material 260 may be formed, attached, and deposited using any of the materials and techniques describe above with respect the first stacked layer 252, channels 256, 258, and deformable conductive material 260 of circuit assemblies 20A-20F. For example, the circuit assembly 20G can include a release layer (not shown)(e.g., similar to release layer 254) attached to the second stacked layer 270.

As illustrated by the non-limiting aspect of FIG. 13B, the via 272 in the second stacked layer 270 aligns with a portion of channel 256 in the first stacked layer 252. Thus, when the via 272 is filled with deformable conductive material 260, it forms a continuous conductive structure with the channel 256, The vias 272, 274 in the second stacked layer 270 may serve numerous functions. For example, vias 272, 274 may function as contact points (e.g., similar to contact points 102 of FIG. 1) for one or more electric devices (e.g., electrical component 104 of FIG. 1). Thus, vies 272, 274, as shown in the non-limiting aspect of FIGS. 13A and 13B, may be used as contact points for an electric component (e.g., a resistor, a capacitor, or any other electric component) that has two connection leads or terminals. As another example, vies 272, 274 may function as circuit elements themselves, such as a transmission line or sensor. As yet another example, vias 272, 274 may electrically connect reusable traces formed by channels 256 and 258 in the first stacked layer 252 with reusable traces in another layer above the second stacked layer 270. The pattern of vias 272, 274 shown in FIGS. 13A and 13B is merely one example, and the pattern may be modified to include any number, shape, arrangement, etc., of conductive passageways.

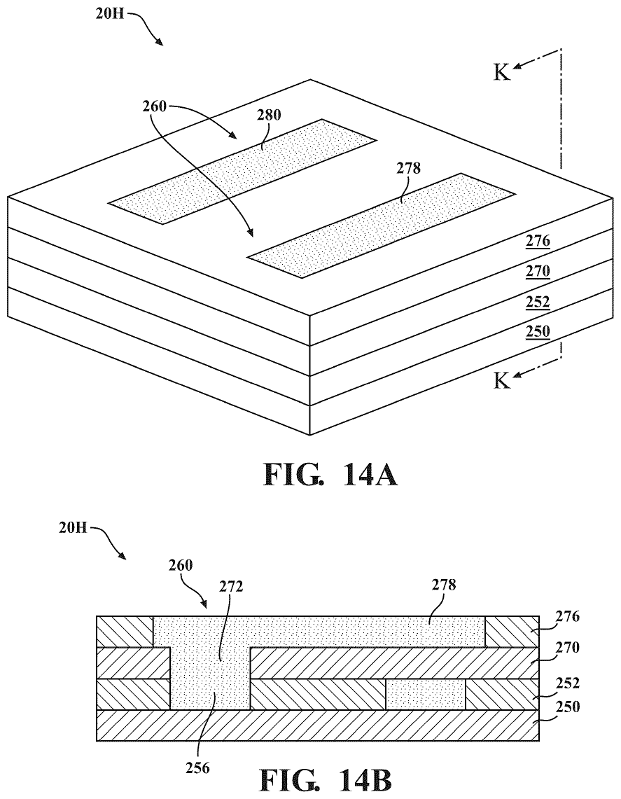

Referring now to FIGS. 14A, a perspective view of a circuit assembly 20H is illustrated with a third stacked layer 276 stacked on the second stacked layer 252, in accordance with at least one non-limiting aspect of the present disclosure. FIG. 14B is a cross-sectional view taken through line K-K of FIG. 14A. FIGS. 14A and 14B can correspond to a step or steps for manufacturing a highly efficient circuit assembly that occurs after a stacking step (e.g., after stacking the third stacked layer 276 on the second staked layer 270). The third stacked layer 276 may be an insulation layer or a stencil layer. The third stacked layer 276 can include a pattern of passages (e.g., channels 278 and 280) that align with the vias 272, 274 in the second stacked layer 270. The third stacked layer 276, channels 278, 280, and deformable conductive material 260 may be formed, attached, deposited, etc. using any of the materials and techniques disclosed above with circuit assemblies 20A-20G. For example, the circuit assembly 20H can include a release layer (not show)(e.g., similar to release layer 254) attached to the third stacked layer 276.

Similar to the patterns of passages in the first stacked layer 252 and the second stacked layers 270, the pattern of passages (e.g., channels 278 and 280) in the third staked layer 276 can serve numerous functions. For example, the pattern of passages of the third stacked layer 276 may function as contact points for one or more electric devices; the pattern of passages may function as circuit elements themselves, for example, as a transmission line or sensor; the pattern of passages may function as reusable traces that are electrically connected to the vias 272 and 274 in the second stacked layer 270; etc. The pattern of passages (i.e., channels 278 and 280) shown in FIGS. 14A and 14B are merely one example, and the pattern may be modified to include any number, shape, arrangement, etc., of conductive passageways.

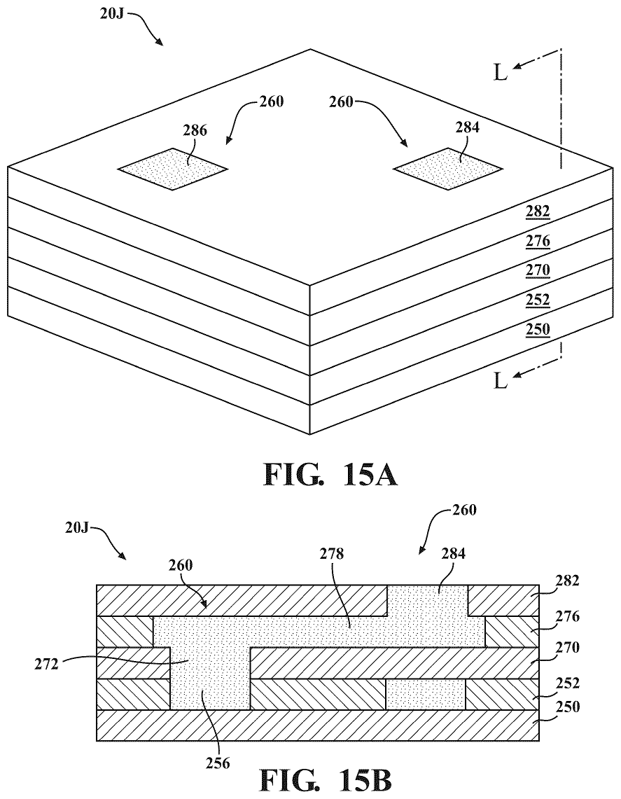

Referring now to FIG. 15A, a perspective view of a circuit assembly 20J is illustrated with a fourth stacked layer 282 stacked on the third stacked layer 276, in accordance with at least one non-limiting aspect of the present disclosure. FIG. 15B is a cross-sectional view taken through line L-L of FIG. 15A. FIGS. 15A and 15B can correspond to a step or steps for manufacturing a highly efficient circuit assembly that occurs after a stacking step (e.g., after stacking the fourth stacked layer 282 on the third stacked layer 276). The fourth stacked layer 282 may be an insulation layer or a stencil layer. The fourth stacked layer 282 can include a pattern of passages (e.g., channels 284 and 286) that align with the channels 278, 280 in the third stacked layer 276. The fourth stacked layer 282, channels 284, 286, and deformable conductive material 260 may be formed, attached, deposited, etc. using any of the materials and techniques disclosed above with circuit assemblies 20A-20H. For example, the circuit assembly 20J can include a release layer (not shown)(e.g., similar to release layer 254) attached to the fourth stacked layer 282.

Similar to the patterns of passages in the first stacked layer 252, the second stacked layers 270, and the third stacked layer 276, the pattern of passages (e.g., channels 284 and 286) in the fourth staked layer 282 can serve numerous functions. For example, the pattern of passages of the fourth stacked layer 282 may function as contact points for one or more electric devices; the pattern of passages may function as circuit elements themselves, for example, as a transmission line or sensor; the pattern of passages may function as vias that are electrically connect to the channels 278 and 280 of the third stacked layer 276 to a second circuit assembly (not shown); the pattern of passages may function as contact points for making “hard-to-soft connections between hard external terminals of an electrical component; etc. The pattern of passages channels 278 and 280) shown in FIGS. 14A and 14B are merely one example, and the pattern may be modified to include any number, shape, arrangement, etc., of conductive passageways.

As is apparent from the non-limiting aspect of FIG. 15B, there is a continuous conductive path through the channel 256 in the first stacked layer 252, via 272, channel 278, and channel 284 (e.g., pad 284). The stacked layers and passages shown in the non-limiting aspects of FIGS. 7A and 7B through 15A and 15B are for purposes of illustration only and can be modified to create any type of circuit arrangement as a complete layup, or when combining multiple stacks as a modular assembly. For example, the order of the layers of including vias and connection points (e.g., pads) and layers including reusable traces can be changed. Additionally, the total number and relative position of the stacked layers and the substrate layer(s) can be changed. Some layers can include reusable traces, vias, and pads or any combination thereof.

Given the number configurations of passages that may be implemented, a person of ordinary skill in the art will understand that any of the stacked layers of the circuit assembly 20 can serve an electric circuit function as well as an insulating function for the stacked layer or layers adjacent to it in the stack. For example, referring again to the non-limiting aspect of FIG. 15A, the fourth stacked layer 282 is shown as an insulation layer at least partially covering the third stacked layer 276, which serves is shown as a stencil layer. In some aspects, any of the stacked layers of circuit assembly 20 that serve as an insulation layers (e.g., the fourth stacked layer 282 as shown in FIG. 15A) configured for minimal deformable conductive material 260 to be exposed when the circuit assembly 20 is installed to its end use application. This may help to prevent the deformable conductive material from being removed from the circuit assembly 20 (e.g., by being pulled out of channels in the staked layers by foreign objects or by inertial forces). In other aspects, where any of the various non-limiting aspects of circuit assembly 20 (e.g., 20A, 20B, 20C, 20D, 20E, 20F, 20G, 20H, 20J) is not in final form, but rather an intermediate manufacturing article, it may not be necessary to limit the amount of deformable conductor in communication with the surroundings. For example, the circuit assembly 20J of FIGS. 15A, B may serve as subassembly that is joined with a second circuit subassembly (not shown) to form a final circuit assembly. The circuit layup of such a non-limiting aspect may optionally have one or more electric components installed to form a circuit assembly. It should be appreciated that such an example demonstrates a modular way to design circuit layups and electrical assemblies. Additionally, it should be noted that any of the circuit assemblies 20 (e.g., 20A, 20B, 200, 20D, 20E, 20F, 20G, 20H, 20J) may exist as a circuit assembly in its final form.

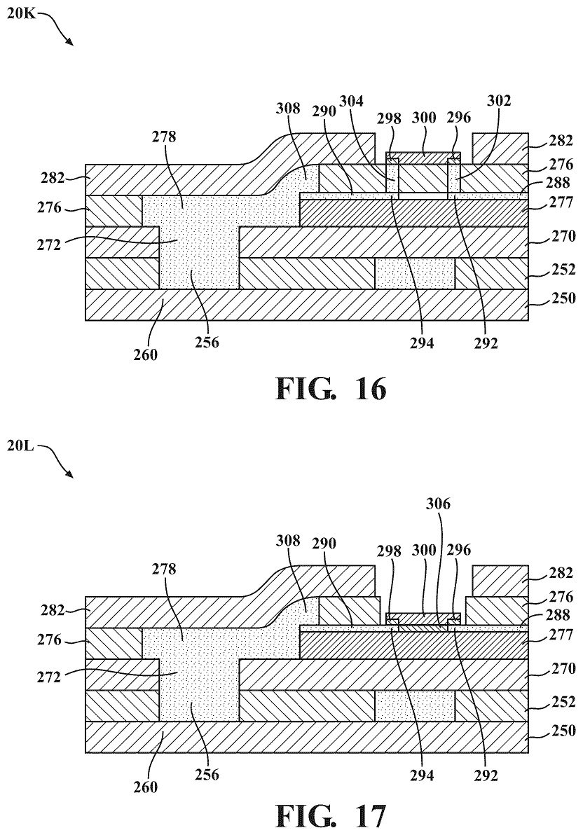

Referring now to FIG. 16, a cross-sectional view of a circuit assembly 20K is illustrated according to at least one non-limiting aspect of the present disclosure. For purposes of illustration, the non-limiting aspect of FIG. 16 is shown having layers similar to those in FIG. 15B. However, in other aspects, circuit assembly 20K may have any number and combination of layers, as explained above. According to the non-limiting aspect of FIG. 16, circuit assembly 20K can include a layer 277, sublayer 277, or portion of a layer 277 (referred to collectively as a sublayer 277). The sublayer may include a pattern of conductive elements (e.g., reusable traces 288, 290) that has been formed thereon and/or therein. In this aspect, the sublayer 277 is interposed between a portion of the second stacked layer 270 and portion of the third stacked layer 276. The third stacked layer 276 and fourth stacked layers 282 can be formed with a step to accommodate the sublayer 277. In other aspect, the sublayer 277 may replace a portion of a stacked layer, an entire stacked layer, or be added as another entire layer. The sublayer 277 may be thinner, thicker or the same thickness as any of the other layers.

In some aspects, any or all of the conductive elements on and/or in layer 277 can include a deformable conductive material (e.g., deformable conductive material 260) and can be deposited using the various deposition methods described herein. In some aspects, the pattern of conductive elements included on and/or in layer 277 can include a mix of deformable and non-deformable conductive elements. The sublayer 277 can be formed from any of the stacked layer and/or substrate layer materials disclosed above and attached to other layers as described above. The pattern of elements can include reusable traces, vias, pads, or circuit elements including transmission lines and sensors, or any combination thereof. The pattern of elements may be formed on the sublayer 277 through any of the techniques described above. In one aspect, some or all of the conductive elements of sublayer 277 can be formed using a printing process, such as, for example, a reel-to-reel (R2R) process. Forming sublayer 277 via a printing process can enable the creation of finer conductive elements to accommodate smaller electric components or interconnects, or to accommodate components or interconnects having generally different characteristics.

According to the non-limiting aspect of FIG. 16, the sublayer 277 includes a pattern of conductive elements including reusable traces 288 and 290. Reusable traces 288, 290 can be connected to pads 292 and 294, the pads 292 and 294 aligning with terminals 296 and 298, respectively, on an electric component 300. Vias 302 and 304 through the third stacked layer 276 can conductively couple the pads 292, 294 with the terminals 296, 298. In one aspect, the electric component 300 can be a bare integrated circuit die on which the terminals 296 and 298 are formed as bonding or contact pads (as shown in the non-limiting aspect of FIG. 16). In other aspects, any other type of electric component (e.g., electric component 104 of FIG. 1) may be used. The electric component 300 can be attached to the third layer 276 using any suitable technique, such as, for example, the connection methods described above with respect to the electrical component 104 and/or IC 116 of FIGS. 1 and 2.

The pattern of conductive elements (e.g., reusable traces 288, 290) formed on or in the sublayer 277 an be interconnected with any other type of reusable traces, vias, pads, components, etc. In the non-limiting aspect of FIG. 16, reusable trace 290 on sublayer 277 is electrically connected to reusable trace 278 in the third stacked layer 276 through hybrid reusable trace/via 308 formed in the step portion of the third stacked layer 276 which accommodates the thickness of the sublayer 277. In other non-limiting aspects, the portion of the third stacked layer 276 over the sublayer 277 may be omitted, and the fourth stacked layer 282 may be formed on a plane defined by the remaining portion of the third stacked layer 276 and the sublayer 277.

Referring now to FIG. 17, a cross-sectional view a circuit assembly 20L is illustrated, in accordance with at least one non-limiting aspect of the present disclosure. The circuit assembly 20L of FIG. 17 may be similar to circuit assembly 20K of FIG. 16, except a portion of the third stacked layer 276 under the electrical component 300 is omitted. The vias 302 and 304 can also be omitted. In some aspects, electrical component 300 can be attached to a surface of the sublayer 277 with a layer of adhesive 306. In some aspects, the terminals 296, 298 can directly contact pads 292 and 294 formed from deformable conductive material.

FIGS. 18A and 18B through 23A and 23B illustrate various intermediate and final circuit assemblies manufactured using a removable stencil, in accordance with non-limiting aspects of the present disclosure. In some aspects, FIGS. 18A and 18B through 23A and 23B can correspond to various steps for methods of manufacturing the intermediate and final circuit assemblies. FIGS. 188, 19B, 20B, 21B, 22B, and 238 are cross-sectional views of FIGS. 18A, 19A, 20A, 21A, 22A, and 23A, respectively.

Referring now to FIG. 18A, a perspective view of a circuit assembly 40A is illustrated prior to placing a removable stencil 452 on a substrate layer 450, in accordance with at least one non-limiting aspect of the present disclosure. FIG. 18B is a cross-sectional view taken through line M-M of FIG. 18A. FIGS. 18A and 188 can correspond to beginning or intermediate step(s) for manufacturing a highly efficient circuit assembly. The substrate layer 450, as well as any additional stacked layers (e.g., encapsulation layers) shown in FIGS. 18A and 18B through 23A and 238 (e.g., layers 470, 482, etc.), may be fabricated from materials disclosed above with respect to the substrate layer 100 of FIG. 1. For example, the substrate layer 450 and encapsulation layer 470 may be fabricated from a readily recyclable polymer material such as TPU. The substrate layer 450 may generally be an uninterrupted sheet of material.

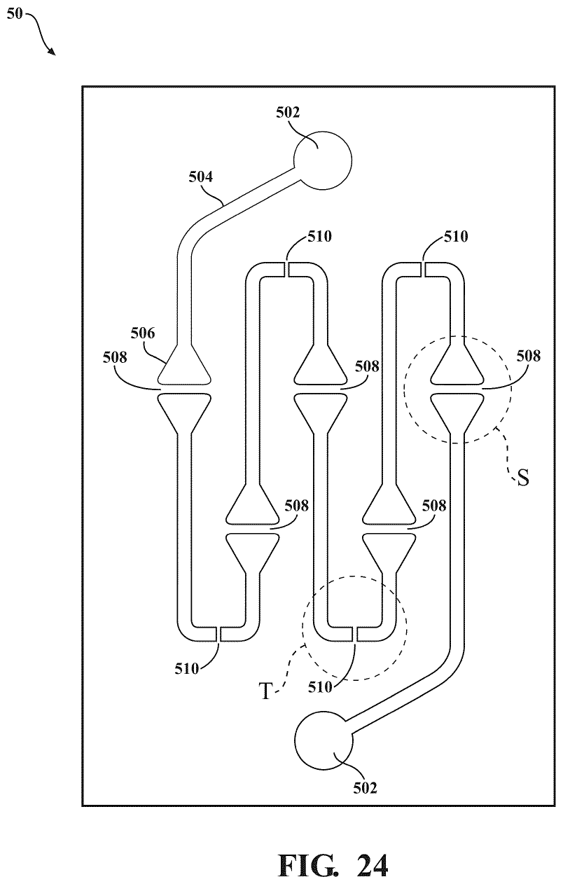

The removable stencil 452 may be constructed from a rigid material and/or durable material (e.g., stainless steel) that includes a pattern of one or more passages (e.g., openings; e.g., channels 453 and 455) configured to at least temporarily house a deformable conductive material in order to form a pattern of deformable conductive material on a surface of the substrate layer 450, as explained in more detail below with respect to FIGS. 19A and 19B through FIGS. 21A and 21B and FIGS. 24 through 26. The channels 453, 455 may be formed in the removable stencil 452 using subtractive techniques, such as, for example, laser cutting, drilling, routing, die cutting, water-jet cutting, chemical etching etc. In other aspects, the removable stencil 452, and thus channels 453, 455, may be formed using an additive manufacturing technique, such as, for example, 3-D printing, pattern deposition, molding (injection, press) etc. Various patterns of channels 435, 455 may be formed in the removable stencil 452 in order to create a desired pattern of deformable conductive material on the substrate layer, for example, as explained in more detail below with respect to removable stencil 50 of FIGS. 24-26.

As mentioned above, removable stencil 452 may be a constructed from a rigid and/or durable material. The use of a rigid and/or durable material to construct removable stencil 425 can allow for the more efficient, reproducible, and cost effective manufacturing of circuit assemblies. For example, mechanically assisted and/or automated processes may be used to place and/or remove the removable stencil 425 to assist with the deposition of deformable conductive material. These mechanically assisted and/or automated processes may include the use of apparatuses such as a movable framework to which the removable stencil 452 is attached. The movable framework can be used to place and remove the stencil 425 in a consistent and reproducible manner. Such processes may also include the use of robotic equipment. Thus, the use of mechanically assisted and/or automated processes to place and remove the removable stencil 425 may allow for the stencil, and therefore the deformable conductive material, to be consistently placed on the substrate layer 450. These processes can enable more precise manufacturing tolerances to be achieved, can reduce defect rates, can create crisper trace boundaries of the patterns of deposited deformable conductive material, and can reduce potential errors related to alignment of the removable stencil 425 on the substrate layer 450. Moreover, these processes can increase manufacturing throughput and reduce labor costs.

Referring now to FIG. 19A, a perspective view of a circuit assembly 40B is illustrated after placing the removable stencil 452 on the substrate layer 450 and overfilling the channels of the removable stencil 425 with deformable conductive material 460, in accordance with at least one non-limiting aspect of the present disclosure. FIG. 19B is a cross-sectional view taken through line N-N of FIG. 19A. FIGS. 19A and 19B can correspond to a step or steps for manufacturing a highly efficient circuit assembly. The deformable conductive material 460 may include any of the deformable conductive materials disclosed above with respect to FIG. 1. In various aspects, the deformable conductive material 460 can be readily reclaimable and/or highly efficient, thus enabling circuit assembly 40 to be highly efficient circuit. For example, the deformable conductive material 460 can include the conductive gel (e.g., a gallium indium alloy) disclosed above. Overfilling the channels 453, 455 of the removable stencil 452 with the disposable conductive material 460 may be performed using any suitable technique such as, for example, extruding, rolling, swabbing, spraying, printing, brushing, deposition, etc. As a result of overfilling channels 453, 455 with deformable conductive material 460, a pattern of deformable conductive material 456, 458 is formed on a surface of the substrate material 450. The pattern of deformable conductive material 456, 458 can correspond to a desired pattern of traces (e.g., traces 456, 458).

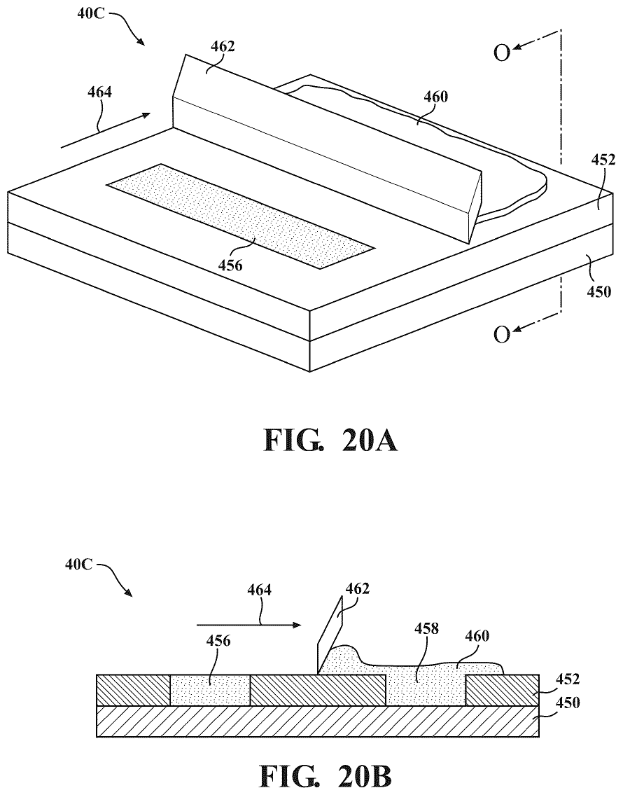

Referring now to FIGS. 20A, a perspective view of circuit assembly 40C is illustrated during wiping of excess deformable conductive material 460 off of the surface of the removable stencil 452, according to at least one non-limiting aspect of the present disclosure. FIG. 20B is a cross-sectional view taken through line O-O of FIG. 20A. FIGS. 20A and 20B can correspond to a step or steps for manufacturing a highly efficient circuit assembly. After the deformable conductive material 460 is deposited onto the removable stencil 452 (e.g., overfilled into channels 453, 455), excess deformable conductive material 460 can be wiped from the surface of the stencil layer 452. The wiping can be performed using a wiping tool 462 by wiping as shown by arrow 464. Wiping tool 462 can be a squeegee including a blade having a resilient characteristic and configured to cause the application of a downward pressure to the surface of the removable stencil 452 while being translated over the surface of the removable stencil 452. Excess deformable conductive material 460 may be collected and used to fill channels or form reusable traces and/or contact points in another circuit assembly and/or can be used to construct patterns of deformable conductive material between additional layers of the same circuit assembly. The various deposition methods described herein can use a singular operation for applying the deformable conductive material 460 between each layer of a circuit assembly. In some aspects, no further operations are necessary to produce functional reusable traces and/or contact points in a circuit assembly.

In some aspects, the wiping process 464 may include the use of a mechanically assisted and/or automated wiping tool 462. For example, the circuit assembly 40C may be placed on a frame attached to a wiping tool 462 configured to slide along a defined path to perform the wiping 464. The use of a mechanically assisted and/or automated wiping processes can increase efficiency, increase manufacturing throughput, and/or reduce labor costs.

As mentioned above with respect to FIGS. 10A and 10B, reclaimed excess deformable material was experimentally found to offer substantially indistinguishable performance compared to virgin stock, as shown in Examples 1 and 2 below, Thus, compared to conventional circuit boards and related methods, the various circuit assemblies and related methods disclosed herein can reduce or eliminate waste production and/or reduce or eliminate resource consumption that results from the deposition of conductive materials. For example, as described in detail above, conventional methods of producing FR4/copper circuit boards often involve various resource-consuming curing, etching, and stripping steps that generate waste materials such as excess etched copper conductor and other spent materials. Moreover, epoxy-based conductive adhesives used to replace soldering are often wasted due to their decreased ability to be reused after curing. Conversely, in various aspects, the deformable conductive material described herein can be deposited onto a circuit assembly and the excess can be collected and reused without consuming resources (e.g., water), without expending energy (e.g., without consuming electricity, without applying heat, without having to solder, etc.), without wasting the deformable conductive material (e.g., because it can be collected and reused), without generating other waste products (e.g. without using cleaning solvents, without chemical etching, etc.), and/or without producing hazardous byproducts (e.g., because the deformable conductive material can be non-hazardous).

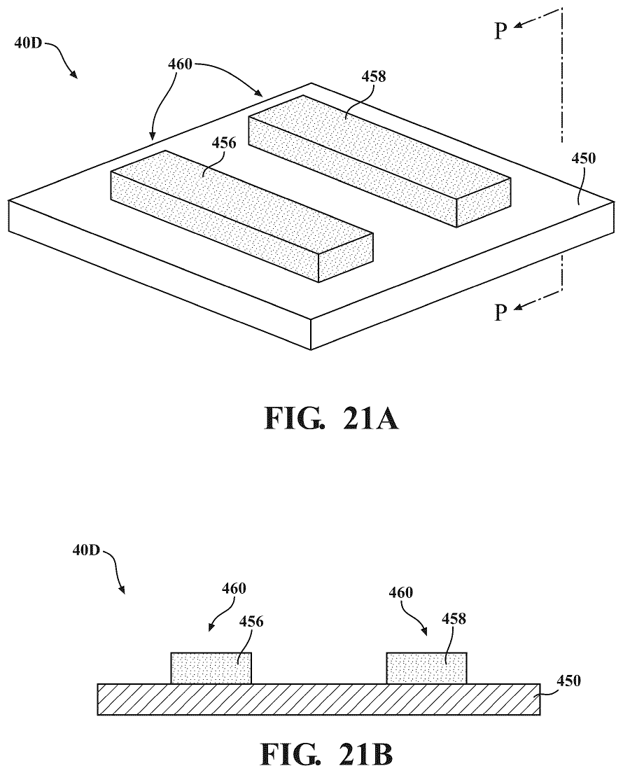

Referring now to FIG. 21A, a perspective view of circuit assembly 40D is illustrated with patterns of deformable conductive material 456, 458 (e.g., traces 456, 458) formed on the surface of the substrate layer 450 after the removable stencil 452 is removed, in accordance with at least one non-limiting aspect of the present disclosure. FIG. 21B is a cross-sectional view taken through line P-P of FIG. 21A. FIGS. 21A and 21B can correspond to a step or steps for manufacturing a highly efficient circuit assembly that occurs after a deposition step (e.g., overfilling and/or wiping step) and a stencil removal step. After the removable stencil 452 is removed from the surface of the substrate layer 450, the patterns of deformable conductive material 456, 458 may remain on the surface of the substrate layer 450, thereby forming a pattern of traces 456, 458 on the surface of the substrate layer 450. Unlike the stencil layer 252 described above with respect to FIGS. 10A and 10B through 12A and 129, the removable stencil 452 does not remain in the circuit assembly 40. Therefore, in some aspects, it may not critical to completely remove all of the excess deformable conductive material from the surface of the removable stencil 452. Because the removable stencil 452 is removed, there is no risk of excess deformable conductive material that remains on the surface of the stencil 425 causing a short circuit in a completed circuit assembly 40.

The circuit assembly 40D of FIGS. 21A and 219 can have utility as fabricated, or it can serve as a base for additional layers. For example, as fabricated, circuit assembly 40D can include pattern of contact points (e.g., contact points 102 of FIG. 1) to engage the terminals (e.g., terminals 106 of FIG. 1) of an electric device (e.g., electrical component 104 of FIG. 1) that may be attached to, adhered to, mounted on, or otherwise supported by, the substrate layer 450, similar to circuit assemblies 10, 12, 14, and 16 described above with respect to FIGS. 1 through 6. The configuration of the pattern of deformable conductive material 456, 458 may be modified to include different numbers, sizes, shapes, etc. of conductive traces and/or contact points (e.g., similar to the various contact points and reusable traces disclosed above with respect to FIGS. 1-6). As another example, as fabricated circuit assembly 40D can be used as a circuit element itself. For example, one or more patterns of deformable conductive material 456, 458 may function as a transmission line, such as, for example, a strip line or as a circuit capacitor.

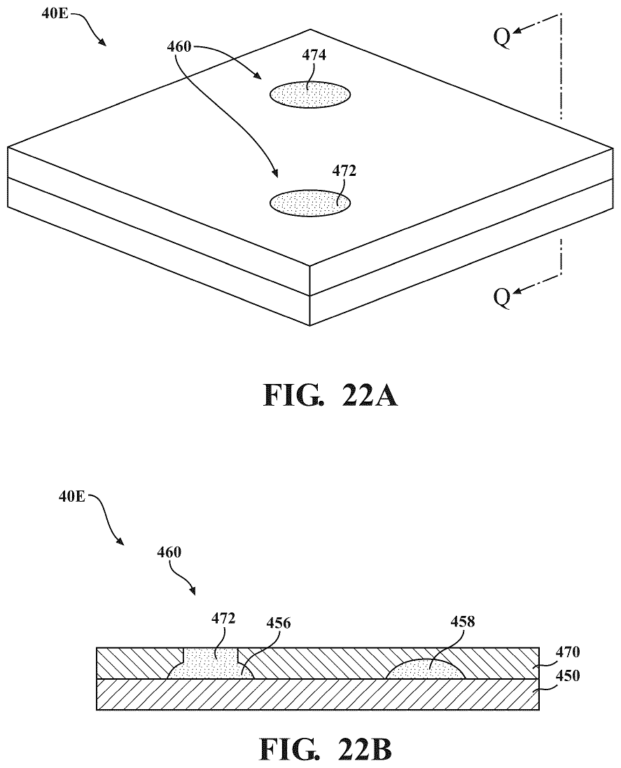

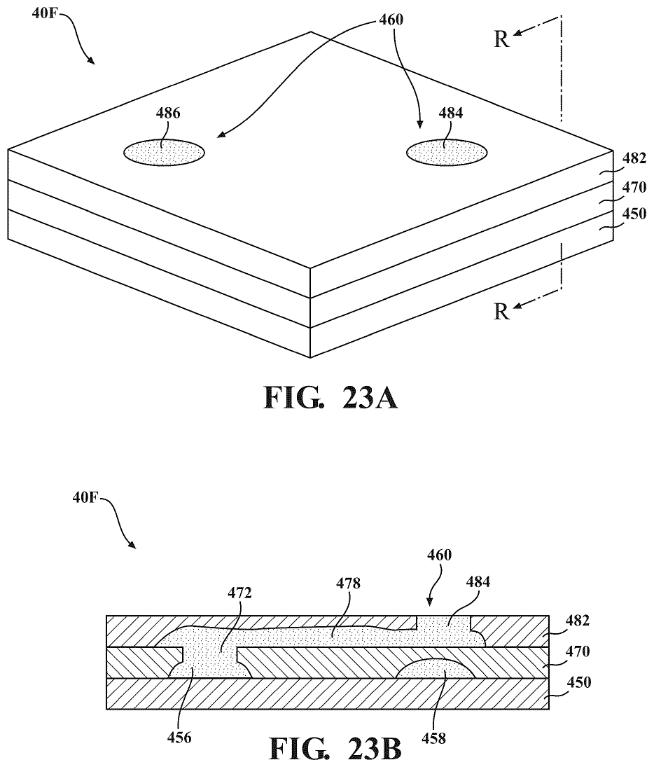

Referring now to FIG. 22A, a circuit assembly 40E is illustrated with a first stacked layer 470 (e.g., an encapsulation layer 470) stacked on the substrate layer 450 having the pattern of deformable conductive material 456, 458 formed thereon, in accordance with at least one non-limiting aspect of the present disclosure. FIG. 22B is a cross-sectional view taken through line Q-Q of FIG. 22A. FIGS. 22A and 22B can correspond to a step or steps for manufacturing a highly efficient circuit assembly that occurs after a stacking step (e.g., after stacking the first stacked layer 470 on the substrate layer 450). The first stacked layer 470 may be an encapsulation layer 470 to encapsulate the pattern of deformable conductive material 456, 458 and/or an insulation layer 470 to insulate the pattern of deformable conductive material 456, 458 from additional deformable conductive material (e.g., pattern 478) deposited between additional layers (e.g. between the first stacked layer 470 and a second stacked layer 482, as shown in FIGS. 23A and 23B). In the non-limiting aspect of FIGS. 22A and 228, the first stacked layer 470 functions as an encapsulation layer 470, and covers at least a portion of the pattern of deformable conductive material 456, 458. The first stacked layer 470 can include a pattern of passages 472, 474. The pattern of passages can be, for example, vias 472, 474 that respectively align with a portion of traces formed by the pattern of deformable conductive material 456, 458. Although the pattern can be produced during any of the aforementioned manufacturing processes, according to some non-limiting aspects, the pattern can be produced in a separate and/or subsequent operation (e.g., cut after unitizing, etc.).

The substrate layer 450 and the first stacked layer 452 may be unitized (e.g., bonded together) using any of the techniques described above with respect to the layers of circuit assemblies 20A-20L in FIGS. 7A and 7B through 17. In some aspects, the substrate layer 450 and the first stacked layer 470 may be unitized through the application of heat, pressure, or a combination thereof. For example, the circuit assembly 40E may be placed on and/or pressed against a heating plate to unitize the layers. In some aspects, pressure may be manually applied to the surfaces of the circuit assembly 40E to unitize the layer. In other aspects, pressure may be mechanically applied, for example, using a pneumatic air press or similar methods. In yet other aspects, a soft and/or spring-like material may pressed against a surface of the substrate layer 450 and/or the first stacked layer 470 when applying pressure to control potential deformation of the patterns of deformable conductive material 456, 458. For example, it may be desirable for the deformable conductive material 456, 458 to slightly deform upon the application of pressure, but not to an extent that the patterns of deformable conductive material 456, 458 lose their intended shape (e.g., potentially causing a short circuit). In one aspect, a foam or other compressible material may be used to control the distribution of pressure applied to the substrate layer 450, the first stacked layer 470, and/or the patterns of deformable conductive material 456, 458. Additional details related to unitizing the layers of the circuit assemblies disclosed herein, as well as details related to controlling the deformation of the deformable conductive material are provided below with respect to FIGS. 24-26.

In various aspects, circuit assembly 40 can include additional layers to create a stacked circuit assembly. For example, referring now to FIG. 23A, a circuit assembly 40F is illustrated with a second stacked layer 482 stacked on the first stacked layer 472, in accordance with at least one non-limiting aspect of the present disclosure. FIG. 23B is a cross-sectional view taken through line R-R of FIG. 23A, FIGS. 23A and 23B can correspond to a step or steps for manufacturing a highly efficient circuit assembly that occurs after placing the removable stencil 452 on a surface of the first stacked layer 472, depositing deformable conductive material 460 into channels 453, 455 of the removable stencil 452 to form a pattern of deformable conductive material 478 thereon, removing the removable stencil 452, and placing the second stacked layer 482 on a surface of the first stacked layer 470 with the pattern of deformable conductive material 478 formed thereon. The second stacked layer 482 may be an encapsulation layer 482 to encapsulate the pattern of deformable conductive material 478 and/or and insulation layer 482 to insulate the pattern of deformable conductive material 478 from deformable conductive material deposited between additional layers (e.g. between the second stacked layer 482 and a third stacked layer (not shown)). In the non-limiting aspect of FIGS. 23A and 23B, the second stacked layer 482 functions as an encapsulation layer 482, and covers at least a portion of the pattern of deformable conductive material 478.

Still referring to FIGS. 23A and 23B, one or more vias of the first stacked layer 470 (e.g. vias 472, 474) can align with one or more of the patterns of deformable conductive material formed on the surface of the first stacked layer (e.g., 478), thereby creating a continuous conductive structure between at least a portion of the patterns of conductive material 456, 458 formed on the substrate layer 450 and at least a portion of the pattern of conductive material 478 formed on the first stacked layer 472. Further, in some aspects, the second stacked layer 482 can include a pattern of passages 484, 486, The pattern of passages can be, for example, vias 484, 486 that respectively align with the pattern of deformable conductive material 478. The vias 484, 486 in the second stacked layer 482 may serve numerous functions. For example, vias 484, 486 may function as contact points, circuit elements, etc. The second stacked layer 482, vias 484, 486, and deformable conductive material 460 may be formed, deposited, unitized, etc. using any of the materials and techniques describe above.

The circuit assembly 40 and methods of making thereof described above with respect to FIGS. 18A and 18 through 23A and 24B can provide for a highly efficient circuit assembly. In some aspects, circuit assembly 40 and methods of making of thereof can share the efficient features of circuit assembly 20 described above with respect to FIGS. 7A and 7B through 17A and 17B, Moreover, circuit assembly 40 and related methods can provide for further sustainability-related improvements. For example, in various aspects, circuit assembly 40 may not employ a stencil layer to form the patterns of deformable conductive material. In fact, the inventors have surprisingly found that the methods described herein with respect to circuit assembly 40 and stencil layer 50 (of FIGS. 24-26) enable the formation of deformable conductive material on layers of the circuit assembly without the need for a stencil layer to electrically insulate adjacent portions of the pattern of deformable conductive material from one another. Thus, circuit assembly 40 may use of less layers (and therefore less layer material, less processing/cutting of the layer material) for each pattern of deformable conductive material that is deposited (e.g., circuit assembly 40 may only require a substrate layer 450 and an encapsulation layer 470 to encapsulate the deformable conductive material whereas circuit assembly 20 may require a substrate layer 250, a stencil layer 252 with deformable conductive material formed therein, and an insulation layer 270). Moreover, in some aspects, each layer of circuit assembly 20 and circuit assembly 40 may be unitized (e.g., bonded together) using heat, pressure, or a combination thereof. As circuit assembly 40 may require less layers, the number of unitizing steps may be decreased and therefore resources such as heat energy, pneumatic air, etc. may be conserved. Further, in some aspects, circuit assembly 40 may conserve material related to release liners as release liners may be used when removing excess deformable conductive material from the stencil layer(s) of circuit assembly 40.

A person of ordinary skill in the art will appreciate that additional stacked layers and patterns of deformable conductive material may be added to circuit assembly 40 to obtain a desired circuit assembly configuration. For example, circuit assembly 40 can include 2, 3, 4, 5, 6, 7, or more than 7 stacked layers with deformable conductive material deposited therebetween.

Given the number of configurations of layers, traces, vias, etc. that may be implemented, a person of ordinary skill in the art will also understand that any of the aspects of the circuit assemblies disclosed herein can be combined. For example, a stencil layer disclosed with respect to circuit assembly 20 may be used in combination with a circuit assembly that also has deformable conductive material deposited therein using the removable stencil disclosed with respect to circuit assembly 40. Moreover, any number and combination of stacked layers, patterns of deformable conductive materials, patterns of passages, etc. may be implemented to obtain a desired circuit assembly configuration.

Referring now to FIG. 24, a plan view of an exemplary removable stencil 50 is illustrated, in accordance with at least one non-limiting aspect of the present disclosure. The exemplary removable stencil 50 is provided to illustrate various features that may be employed related to the removable stencils disclosed herein, such as the removable stencil 452 describe above with respect to FIGS. 18A and 18 through 23A and 24B. A person of ordinary skill in the art will appreciate that a vast variety of stencil designs may be implemented to achieve a desired pattern of deformable conductive material based on the aspects disclosed herein.

The removable stencil 50 may be constructed using any of the techniques described above with respect to the removable stencil 452. The removable stencil 50 can include various openings and/or channels configured for deformable conductive material to be deposited therein. As described in detail above, after deposition of the deformable conductive material into channels of the removable stencil 50, upon removal of the removable stencil 50 from a surface of a layer, a pattern of deformable conductive material can remain on the surface of a layer. In the non-limiting aspects of FIG. 24, the removable stencil 50 includes contact point openings 502 and trace channels 504. The pattern of deformable conductive material left by contact point openings 502 may correspond to vias of an encapsulation layer and the pattern of deformable conductive material left by channels 504 may correspond to a desired trace pattern.

In various aspects, the removable stencil 50 may include various tabs 508, 510. These tabs 508, 510 may be configured to improve the structural characteristics of the removable stencil 50. For example, tabs 508, 510 may be included to help ensure that the removable stencil 50 does not break or otherwise fail upon construction or after repeated use, for example, because of the breaks in the structure caused by channels formed therein. However, in some aspects, the resulting pattern of deformable conductive material deposited to a layer using the removable stencil 50 may include gaps left by tabs 508, 510. Therefore, various design parameters may be optimized and/or adjusted to ensure that gaps left in the pattern of deformable conductive material by tabs 508, 510 are not retained in the competed circuit assembly. Design parameters may also be optimized to ensure that the removable stencil 50 is structurally sound. Aspects of these deign parameters are explained in more detail below.

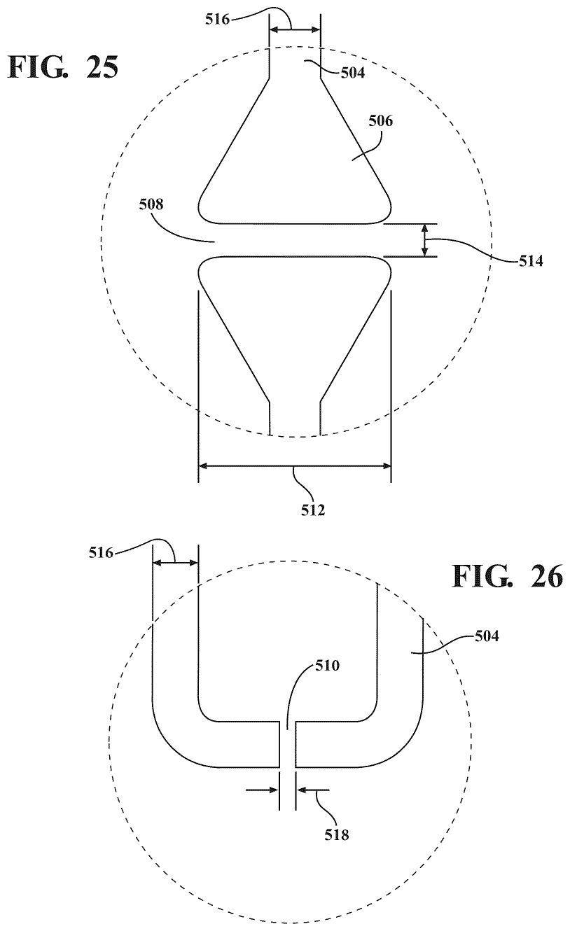

Referring now to FIGS. 25, a detailed view S of the exemplary removable stencil 50 of FIG. 24 is illustrated, in accordance with at least one non-limiting aspect of the present disclosure. FIG. 25 illustrates of a portion of channels 504 and flared channels 506 of the removable stencil 50. The channels 504 have a channel width 516 and the flared channels 510 have a flared channel width 512. Further, tab 508 has a tab width 514. The flared channels 506, flared channel widths 512, tab width 514, channel widths 516, and/or the thickness of the removable stencil 50 (not shown) may be configured such that resulting patterns of deformable conductive material “heal” after the removable stencil is removed from the surface of a layer. As used herein, the term “heal” or “healing” when used with respect to the deformable conductive material can mean the joining together and/or connecting of previously separated portions of the pattern of deformable conductive material such that a continuous conductive pathway is formed.

In some aspects, the channel width 516 may be in a range of 0.05 mm and 2.0 mm, such as a range of 0.1 mm and 1.0 mm, and/or may be about 0.2 mm, about 0.3 mm, about 0.4 mm, about 0.5 mm, about 0.6 mm, about 0.7 mm, about 0.8 mm, or about 0.9 mm. In some aspects, the flared channel width 512 may be in a range of 0.05 mm and 5.0 mm, such as a range of 0.1 mm and 4.0 mm, or 0.5 mm and 3.0 mm, and/or may be about 0.8 mm, about 0.9 mm, about 1.1 mm, about 1.2 mm, about 1.3 mm, about 1.4 mm, about 1.5 mm, about 1.6 mm, about 1.7 mm, about 1.8 mm, about 1.9 mm, or about 2.0 mm. In some aspects, the tab width 514 may be in a range of 6.05 mm and 3.0 mm, such as a range of 0.05 mm and 1.0 mm, and/or may be about 0.06 mm, about 0.07 mm, about 0.08 mm, about 0.09 mm, about 0.1 mm, about 0.2 mm, about 0.3 mm, about 0.4 mm, or about 0.5 mm. In some aspects, the stencil thickness may be in a range of 0.01 mm and 5.0 mm, such as a range of 0.05 mm and 1.0 mm, and/or may be about 0.06 mm, about 0.07 mm, about 0.08 mm, about 0.09 mm, about 0.1 mm, about 0.2 mm, about 0.3 mm, about 0.4 mm, about 0.5 mm, about 0.6 mm, about 0.7 mm, about 0.8 mm, about 0.9 mm, or about 1.0 mm. In other aspects, the flared channel width 512 may be in a range from about 1.1 to 2.2, about 1.15 to 1.75, or about 1.4 to 1.6 times the width of the channel width 516.

Referring now to FIGS. 26, a detailed view T of a channel 504 and a tab 510 of the exemplary removable stencil 50 of FIG. 24 is illustrated, in accordance with at least one non-limiting aspect of the present disclosure. The channel 504 may have a channel width 516 and tab 510 may have a tab width of 518. The channel width 516, tab width 518, and/or the thickness of the removable stencil 50 (not shown) may be configured such that patterns of deformable conductive material “heal” after the removable stencil is removed from the surface of a layer. In some aspects, the tab width 518 may be in a range of 0.05 mm and 2.0 mm, such as a range of 0.05 mm and 1.0 mm, and/or may be about 0.06 mm, about 0.07 mm, about 0.08 mm, about 0.09 mm, about 0.1 mm, about 0.2 mm, about 0.3 mm, about 0.4 mm, or about 0.6 mm. In other aspects, the tab width 518 may be in a range from about 1 to about 3, about 1.1 to 1.7, or about 1.4 times the thickness of the stencil 50. In some aspects, the stencil 50 may have thickness ranging from about 0.08 mm to about 0.50 mm, about 0.10 mm to about 0.20 mm, or about 0.13 mm.

Referring now to FIGS. 24 through 26, in one aspect, the channels 504, flared channels 510, tab widths 514, 518, channel widths 516, and/or the thickness of the removable stencil 50 (not shown) can be configured such that resulting pattern of deformable conductive material heals when heat and/or pressure is applied to unitize surrounding layers of the circuit assembly. For example, the removable stencil 50 may be used to deposit a pattern of deformable conductive material to a substrate layer. An encapsulation layer may be placed on the substrate layer with the pattern of deformable conductive material formed thereon. The application of heat and/or pressure to the resulting circuit assembly may cause the pattern of deformable conductive material left by the flared channels 506 to deform such that the pattern of deformable conductive material heals, thereby forming a continuous conductive pathway. Similarly, the application of heat and/or pressure to the resulting circuit assembly may cause the portions of the pattern of deformable conductive material left by channels 504 proximate to the sides of tabs 510 to deform such that the pattern of deformable conductive material heals, thereby forming a continuous conductive pathway.

In some aspects, various other design parameters related to the removable stencil 50 and the unitization process may be adjusted and/or optimized to ensure that the patterns of deformable conductive material heal while also ensuring that the removable stencil 50 is structurally sound. In one aspect, the positions of the channels 504, the flared channels 506, and the tabs 508, 510 may be optimized for structural integrity. As one example, the number of tabs 508, 510 may be selected to ensure that the removable stencil 50 is structurally sound. As another example, the positions of the flared channels 506 may be selected to ensure that the removable stencil 50 is structurally sound (e.g., the positions of the flared channels 506 may be staggered as shown in FIG. 24).

In some aspects, the properties of the deformable conductive material and/or the properties of the layers surrounding the patterns of the deformable conductive material may be adjusted and/or optimized to ensure that the patterns of deformable conductive material heal upon unitization of the surrounding layers. For example, the deformable conductive material may be optimized to have a viscosity such that the deformable conductive material is able to heal upon unitization of the layers but not such that the deformable conductive material overly deforms and does not achieve the intended pattern. As another example, an adhesive characteristic and/or viscosity of the deformable conductive material may be optimized such that it remains on the substrate layer upon removal of the removable stencil 50 and but does not adhere to the channels 504, 506 of the stencil thereby lifting the deformable conductive material off of the substrate layer. In some aspects, a viscosity of the deformable conductive material may, when under high shear (e.g., in motion), be in a range of about 10 Pascal seconds (Pats) and 500 Pa*s, such as a range of 50 Pa*s and 300 Pa*s, and/or may be about 50 Pa*s, about 60 Pa*s, about 70 Pa*s, about 80 Pa*s, about 90 Pa*s, about 100 Pa*s, about 110 Pa*s, about 120 Pa*s, about 130 Pa*s, about 140 Pa*s, about 150 Pa*s, about 160 Pa*s, about 170 Pa*s, about 180 Pa*s, about 190 Pa*s, or about 200 Pa*s. In some aspects, a viscosity of the deformable conductive material may, when under low shear (e.g., at rest), be in a range of 1,000,000 Pa*s and 40,000,000 Pa*s and/or may be about 10,000,000 Pa*s, about 20,000,000 Pa*s, about 30,000,000 Pa*s, or about 40,000,000 Pa*s.

In some aspects, parameters related to the heat, pressure, and/or other tooling used to unitize layers surrounding the deformable conductive material may be optimized to ensure that the patterns of deformable conductive material heal upon unitization of the surrounding layers. For example, the amount of heat applied (and/or temperature setting used) to unitize the surrounding layers may be optimized such that the deformable conductive material deforms enough to heal but not so much that the deformable conductive material overly deforms and does not achieve the intended pattern. As another example, the pressured applied to unitize the surrounding layers may be optimized such that the deformable conductive material deforms enough to heal but not so much that the deformable conductive material overly deforms and does not achieve the intended pattern.

In some aspects, a pressure applied to unitize layers of a circuit assembly can be in a range of 0.5 psi and 20 psi, such as a range of 1.0 psi and 10 psi, and/or may be about 1.0 psi, about 2.0 psi, about 3.0 psi, about 4.0 psi, about 5.0 psi, about 6.0 psi, about 7.0 psi, about 8.0 psi, about 9.0 psi, or about 10 psi. In some aspects, a heat applied to unitize layers of a circuit assembly can include heating the circuit assembly or a portion thereof at a temperature in range of 50° C. and 250° C., such as a range of 100 CC and 200° C., and/or at a temperature of about 100° C., about 110° C., about 120° C., about 130° C., about 140° C., about 150° C., about 160° C., about 170° C., about 180° C., about 190° C., or about 200° C.

In some aspects, tooling may be used and parameters thereof may be optimized to control the distribution of pressure applied when unitizing the circuit assembly. In some aspects, the tooling used may include a foam material, such as closed-cell silicon foam. The foam material may be positioned on one and/or both surfaces of the circuit assembly during unitization. In one aspect, the softness of the foam may be optimized to control the deformation of the deformable conductive material during unitization. In some aspects, the foam can be an ultra-soft foam.

Any of the non-limiting aspects of circuit assembly 20, circuit assembly 40, and/or any of the other circuit assemblies disclosed herein can be stacked together. In other aspects, one or more internal stacked layers can have a cutout section to accommodate the height of an electrical component (e.g., to accommodate the height of an integrated circuit package). In yet other aspects, the electrical component (e.g., resistors, capacitors, smaller IC packages, bare IC dies, etc.) may be small enough to place between layers, especially if the layers are relatively soft and or pliable.

In various aspects, one or more of the stacked layers, encapsulation layers, and/or substrate layers of any of the circuit assemblies disclosed herein may be formed from a resilient and stretchable TPU such as from the Lubrizol® Estane® 58000 series, for example, 58238. In other aspects, one or more of the stacked layers, encapsulation layers, and/or substrate layers of any of the circuit assemblies disclosed herein may be formed from a comparatively more rigid material such as injection molded using Lubrizol® Estane® S375D.

In various aspects, any of the circuit assemblies disclosed herein can include Epoxy-based materials, such as, for example, B-stage resin films. The Epoxy-based materials can be used as an additional discrete component to provide a self-adhesive surface for bonding electric components to any layer and/or for bonding layers to each other. In various other aspects, sustainability all layers, adhesives and encapsulants of any of the circuit assemblies disclosed herein can may be made from thermally activated adhesives, such as, for example, thermoplastic polyurethane (PU) adhesives (e.g., from Bemis or Framis), In yet other aspects, any of the layers, adhesives, and/or encapsulants of the circuit assembly can include thermoset adhesives such as, for example, silicones, acrylics, and any pressure sensitive adhesive of any chemistry. In the case of encapsulant materials, (e.g., encapsulates applied to terminals of an electric component), the concentration of thermoset material included in the encapsulant may be minimal, allowing the material to be readily recyclable. In one aspect, the circuit assemblies disclosed herein can include fillers including thermoset materials. Fillers including thermoset material may be reused in a “re-grind” format to strengthen, modify, or lower the cost of articles made from a similar thermosetting material.

The various materials, methods, and components described herein can provide for highly efficient circuit assemblies. The various circuit assemblies disclosed herein may be highly efficient, for example, compared to etched FR4/copper circuit boards and circuit boards employing epoxy-based conductive adhesives. Moreover, the circuit assemblies disclosed herein, including circuit assemblies including a deformable conductive material and stacked layers, may not require the use of reinforcements in the layer materials themselves (e.g., chopped fiber reinforcements). Reinforcements used in traditional circuit boards make recycling and reusing the circuit board materials challenging, messy, and harmful for workers processing discarded electronics made from these types of circuit boards. For example, traditional circuit board materials typically must be ground up, and the resulting “re-grind” has very few uses in consumer products. The devices, systems, and methods discussed herein can enable a circular manufacturing chain, and/or an easily recyclable circuit assembly including materials may be recycled and used again in other circuit assemblies, or other consumer products.

Circuit assemblies constructed according to the various aspects disclosed herein can result in highly functional circuit assemblies that may reduce the cost of the assembly. For example, some various aspects of the circuit assemblies disclosed herein may allow for the use of less expensive unpackaged electronic devices. Moreover, other aspects of the circuit assemblies disclosed herein may eliminate the need for soldering, Yet other aspects of the circuit assemblies disclosed herein may provide for improved reliability because the elimination of soldering may reduce the energy consumption (e.g., heating) associated therewith. And yet other aspects of the circuit assemblies disclosed herein may provide for improved cooling by eliminating device packaging which can serve as a barrier to heat dissipation.

Referring now to FIG. 27, a flow diagram for a method 1000 for reclaiming material from a highly efficient circuit assembly is illustrated, in accordance with at least one non limiting aspect of the present disclosure. The highly efficient circuit assembly discussed with respect to FIG. 27 can be any of the highly efficient circuit assemblies 10, 12, 14, 16, 20 and 40 discussed above with respect to FIGS. 1 through 26. The highly efficient circuit assembly can include an electrical component, a substrate layer, and a deformable conductive material. In some aspects, the highly efficient material can include one or more stacked layer(s). In other aspects, the highly efficient circuit assembly can include an encapsulant material and/or an adhesive material. The method 1000 can proceed by removing 1002 the electrical component from the circuit assembly. The method 1000 can further include heating 1004 the highly efficient circuit assembly to a melting temperature of the substrate layer to form a melted substrate layer. In one aspect, heating 1004 the substrate layer to a melting temperature of the substrate layer can cause the substrate layer to be separated from or melted together with other layers (e.g., stacked layers) that are included in circuit assembly and caused to flow. The deformable conductive material (e.g., the conductive gel disclosed herein; the gallium-indium alloy gel disclosed herein, etc.) can have an extremely high temperature tolerance, maintaining a fluid state up to approximately 1300° C.

The method 1000 can further include 1006 separating the deformable conductive material from the melted substrate layer to obtain reclaimed deformable conductive material and reclaimed substrate layer material. In experiments, the inventors heated a highly efficient circuit assembly including a deformable conductive material (i.e., a gallium-indium alloy gel material) and TPU substrate and stacked layers to a flow temperature of the layers. The inventors discovered that heating the layers to the flow temperature allowed the deformable conductive material, by virtue of its surface tension characteristics, to be easily separate from the melted layer material.

In another aspect, the method 1000 can include heating the highly efficient circuit assembly to a melting temperature of the stacked layer to form a melted stacked layer, and separating the deformable conductive material from the melted stacked layer to obtain reclaimed deformable conductive material and reclaimed stacked layer material

In another aspect, the method 1000 can include heating the circuit assembly to a melting temperature of the encapsulant material, wherein removing the electrical component from the circuit assembly occurs after heating the circuit assembly to the glass transition temperature of the encapsulant. In yet another aspect, the method 1000 can include heating the circuit assembly to a glass transition temperature of the adhesive material, wherein removing the electrical component from the circuit assembly occurs after heating the circuit assembly to the glass transition temperature of the adhesive material. Heating the circuit assembly to the melting temperature and/or the glass transition temperature can allow the electrical component to be easily extracted for re-use in other circuit assemblies. The temperatures required for heating can be lower than those experienced by electric components in standard circuit assembly production, and as such will not damage the components.

Referring now to FIG. 28, a flow diagram for a method 2000 for recycling a reclaimed deformable conductive material is illustrated, in accordance with at least one-non limiting aspect of the present disclosure. The deformable conductive material discussed with respect to FIG. 28 can be the various deformable conductive materials discussed above with respect FIGS. 1-26. The method 2000 can proceed by providing 2002 a reclaimed deformable conductive material including a metal alloy and a metal oxide formed from exposure of the metal alloy to air. In one aspect, the reclaimed deformable conductive material can be reclaimed according the method 1000 described above with respect to FIG. 27.

Referring still to FIG. 28, the method 2000 can further include exposing 2004 the reclaimed deformable conductive material to an acid solution thereby reacting the metal oxide with the acid solution to obtain a pure liquid metal alloy. In one aspect, exposing the reclaimed deformable conductive material to an acid solution can cause the metal oxide to react with the acid to form a metallic salt and water. This reaction can help to remove the metal oxide from the metal alloy to obtain the pure liquid metal alloy.

The method 2000 can further include removing 2006 the pure liquid metal alloy from the acid solution. In some aspects, the amount of pure liquid metal alloy removed from the acid solution is no less than 55 wt. % of the metal alloy used to originally manufacture the reclaimed deformable conductive, such as, for example, no less than 55 wt,%, 60 wt. %, 65 wt. %, 70 wt. %, 75 wt,%, 80 wt. %, 85 wt. %, 90 wt. %, or no less than 95 wt. % of the metal alloy used to originally manufacture the reclaimed deformable conductive material. In another aspect, the method 2000 can further include manufacturing new deformable conductive material from the pure liquid metal alloy. Thus, recycling the reclaimed deformable conductive material can enable the deformable conductive material to be reused in production of new circuits with no degradation in electrical characteristics.

In another aspect, exposing 2004 the reclaimed deformable conductive material to an acid solution can further include mixing the deformable conductive material in the acid solution to obtain the pure liquid metal alloy. In one aspect, the reclaimed deformable conductive material includes microparticles. Mixing the deformable conductive material in the acid solution can remove the microparticles to obtain the pure liquid metal alloy. In another aspect, mixing the deformable conductive material in the acid solution can cause the microparticles to float on the surface of the acidic solution, allowing the liquid metal to be extracted. In one aspect, mixing the deformable conductive material in the acid solution to obtain the pure liquid metal alloy includes mixing the deformable conductive material in the acid solution for no less than two days. An exemplary process for recycling the reclaimed deformable conductive material carried out using the method above is detailed below with respect to Example 3.

In another aspect, the method 2000 can include extracting microparticles from the acid solution. In yet another aspect, the method 2000 can include manufacturing new deformable conductive material from the extracted microparticles.

In another aspect, the method 2000 can include collecting the acid solution for reuse in a subsequent process for recycling a reclaimed deformable conductive material. For example, the acid solution may be reused after extracting the pure liquid metal alloy and the microparticles.

In another aspect, the deformable conductive material can include a conductive gel. In one aspect, the deformable conductive material can include a gallium alloy with microparticles suspended therein. In another aspect, the pure liquid metal alloy can include the gallium alloy. In yet another aspect, the acid solution can include hydrochloric acid.

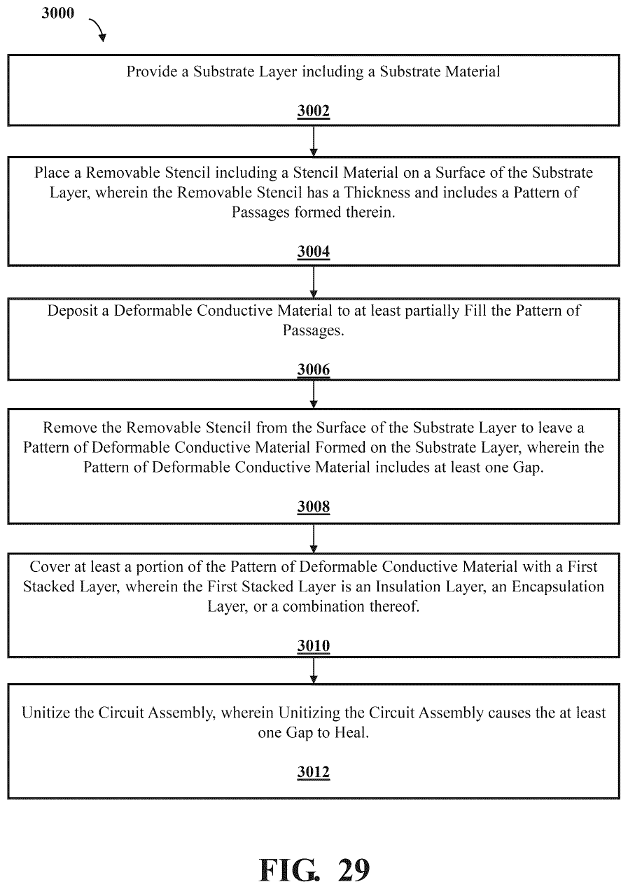

Referring now to FIG. 29, a flow diagram for a method 3000 for manufacturing a highly efficient circuit assembly is illustrated, in accordance with at least one-non limiting aspect of the present disclosure. The deformable conductive material, substrate layer, encapsulation layer, insulation layer(s), and removable stencil discussed with respect to FIG. 29 can in many aspects be similar to the various deformable conductive materials, substrate layers, encapsulation layers, insulation layers, and removable stencils discussed herein. The method 3000 can proceed by providing 3002 a substrate layer including a substrate material. The substrate material can include any of the various substrate materials described herein. The method 3000 can further include placing 3004 a removable stencil including a stencil material on a surface of the substrate layer, wherein the removable stencil can have a thickness and can include a pattern of passages formed therein. In some aspects, the thickness, pattern of passages, and other features of the removable stencil can be configured and/or optimized, for example, based on the various parameters discussed above with respect to FIGS. 24 through 26. To provide a few examples, the pattern of passages can include a trace feature having a trace width, a trace flare feature having a flare width, a staggered pattern of trace flare features, a tab having a tab width, and/or a via feature having a via diameter.

Still referring to FIG. 29, the method 3000 can include depositing 3006 a deformable conductive material to at least partially fill the pattern of passages. In some aspects, the deformable conductive material can be configured and/or optimized based on the various parameters discussed above with respect to FIGS. 24 through 26. For example, as described above, the deformable conductive material may be optimized to have a viscosity such that the deformable conductive material is able to heal upon unitization 3012 (see below) of layers of the circuit assembly but not such that the deformable conductive material overly deforms and does not achieve an intended pattern. As another example, an adhesive characteristic and/or viscosity of the deformable conductive material may be optimized such that the deformable conductive material remains on the substrate layer upon removal 3008 (see below) of the removable stencil and does not adhere to the pattern of passages of the stencil thereby lifting the deformable conductive material off of the substrate layer.

The method 3000 can further include removing 3008 the removable stencil from the surface of the substrate layer to leave a pattern of deformable conductive material formed on the substrate layer. In various aspects, the pattern of deformable conductive material can include at least one gap. In one aspect, the at least one gap can correspond to a tab of the removable stencil.

The method 3000 can further include covering 3010 at least a portion of the pattern of deformable conductive material with a first stacked layer, wherein the first stacked layer is an insulation layer, an encapsulation layer, or a combination thereof.

In one aspect of the method 3000, the first stacked layer can include the encapsulation layer. In another aspect, the method 3000 can include unitizing 3012 the circuit assembly, wherein unitizing the circuit assembly causes the at least one gap to heal. In some aspects, unitizing the circuit assembly can include heating at least a portion of the circuit assembly. In another aspect, unitizing the circuit assembly can include applying pressure to at least one surface of the circuit assembly. The heating and/or applying pressure can be optimized based on the various parameters discussed above with respect to FIGS. 24-26.

In another aspect, the method 3000 can include providing (e.g. forming) at least one opening in the first stacked layer, the substrate layer, or a combination thereof. In one aspect, the at least one opening can be formed prior to 3012 unitizing the circuit assembly. In another aspect, the at least one opening can be formed after 3012 unitizing the circuit assembly.

In another aspect, after covering 3010 at least a portion of the pattern of deformable conductive material with the first stacked layer, the method 3000 can include placing the removable stencil on the first stacked layer, repeating the steps of 3006 depositing the deformable conductive material and removing 3008 the removable stencil, and covering at least a portion of the pattern of deformable conductive material formed on the first staked layer with a second stacked layer. In one aspect, the method 3000 can include unitizing 3012 the circuit assembly including the substrate layer, the first stacked layer, and the second stacked layer. The unitizing can cause at least one gap of the pattern of deformable conductive material formed on the first stacked layer to heal.

In another aspect, after covering 3010 at least a portion of the pattern of deformable conductive material with the second stacked layer, the method 3000 can include placing the removable stencil on the second stacked layer, repeating the steps of 3006 depositing the deformable conductive material and removing 3008 the removable stencil, and covering at least a portion of the pattern of deformable conductive material formed on the second staked layer with a third stacked layer. In one aspect, the method 3000 can include unitizing 3012 the circuit assembly including the substrate layer, the first stacked layer, the second stacked layer, and the third stacked layer. The unitizing can cause at least one gap of the pattern of deformable conductive material formed on the first stacked layer to heal.

In another aspect, after covering 3010 at least a portion of the pattern of deformable conductive material with the third stacked layer, the method 3000 can include repeating the steps of placing the removable stencil, 3006 depositing the deformable conductive material, removing 3008 the removable stencil, and covering at least a portion of the resulting pattern of deformable conductive material until a desired number of layers has been achieved. In this aspect, the method 3000 can include unitizing 3012 the circuit assembly including the desired number of layers. The unitizing can cause at least one gap of the pattern of deformable conductive material formed between at least one of the layers to heal.

In another aspect, the method 3000 can include attaching an electrical component to the substrate layer and/or a stacked layer (e.g., the first stacked layer, the second stacked layer, etc.). The electrical component can include any of the various electrical components described herein. For example, the electrical component can include a polyimide flex circuit, a resistor, a capacitor, a processor, a chip, a contact (e.g., a copper contact, goal contact, silver contact, palladium contact, a combination thereof, etc.), a pin out, a connector, etc.

In another aspect, the method 3000 can include attaching a lockout and/or stiffener layer to the circuit assembly. For example, the lockout and/or stiffener layer can be placed in between two layers of the circuit assembly (e.g., between the substrate layer and the first stacked layer, between the first stacked layer and the second stacked layer, etc.). As another example, the lockout and/or stiffener can be placed on an outer layer of the circuit assembly (e.g., an outer surface of the substrate layer, an outer surface of the encapsulation layer). In some aspects, the lockout and/or stiffener can be similar to the layer 126 discussed above with respect to the circuit assembly 12 of FIG. 3E.

Any of the various circuit assemblies, circuit assembly components (e.g., layers, deformable conductive materials, electrical components, etc.), and methods described herein can be combined to achieve a desired circuit assembly configuration and/or a method for reclaiming/recycling various materials thereof.

### EXAMPLES

### Examples 1 and 2

### Resistance of a Deformable Conductive Material Reclaimed During Circuit Assembly Manufacture

Examples 1 and 2 shown in Table 1 below correspond to experimentally measured resistance values of samples of deformable conductive material virgin stock compared with experimentally measured resistance values for samples of deformable conductive material after it was reclaimed during the circuit assembly manufacturing process. Specifically, the reclaimed deformable conductive material was collected after a wiping process similar to the wiping process described with respect to FIGS. 10A and 10B. Examples 1 and 2 indicate that the resistance values of the reclaimed material and virgin stock are within the typical margin of variance for the measured resistance of the virgin stock.

TABLE 1
Initial and reclaimed resistance of exemplary
deformable conductive material

| Circuit | Virgin Deformable | Reclaimed Deformable |
|---|---|---|
| Assembly | Conductive Material (Ω) | Conductive Material |
| Example 1 | 2.3 | 2.3 |
| Example 2 | 2.2 | 2.4 |

### Example 3

Recycling Deformable Conductive Gel the is Reclaimed from a Circuit Assembly Overview

A deformable conductive gel, designated as MG5 (Metal Gel 5), and having a composition including a eutectic alloy of gallium (68.5 wt. %), indium (21.5 wt. %), and tin (wt. 10%) with microparticles suspended therein, was reclaimed from a circuit assembly using the reclaiming process described above with respect to FIG. 27. The reclaimed MG5 was processed to yield a pure liquid gallium-indium-tin metal alloy, as explained in detail below. The resulting pure liquid metal alloy can subsequently be used to produce more (i.e., recycled) MG5 or another formulation of a similar deformable conductive material. The “waste” products resulting from this recycling process included only a small amount of residual gallium oxide and gallium chloride. The recycling process also produces the microparticles which were in the MG5 initially and which may be re-used to produce more (i.e., recycled) MG5 or another formulation of a similar deformable conductive material.

### MG5 Manufacturing and Gallium Oxide Formation

Generally, a thin layer of gallium oxide can form on the surface gallium in the presence of air. To manufacture MG5 conductive gel, gallium oxide is allowed to form and is distributed through the gallium-indium-tin liquid metal alloy forming a novel microstructure/nanostructure within the liquid metal alloy to form a Bingham plastic. The micro and nanostructures are blended within the mixture, for example through sonication or other mechanical means that entrains air into the mixture. In some aspects, the sonication may introduce cavitation at the surface of the mixture thereby entraining air into the mixture. Thus, the mixture can include a colloidal suspension of micro and nanostructures within the gallium alloy/gallium oxide mixture. For a detailed description of MG5 and similar conductive gel formulations and manufacturing methods, see the aforementioned International Patent Application No. PCT/US2017/019762 titled LIQUID WIRE, which was filed on Feb. 27, 2017 and published on Sep. 8, 2017 as International Patent Publication No. WO2017/151523A1.

MG5 gel is a stiff paste which can be patterned into complex geometries. Thus, MG5 can be used to form, for example, electric circuit assemblies, circuit layups, stacks, etc. MG5 is more mechanically stable than unmodified liquid metal alloys and has excellent adhesion characteristics. Over long periods of time, or through repeated patterning and handling (typically over the course of many months or even years), or after being reclaimed from a circuit layup, the amount of oxide in the gel may increase causing deteriorated mechanical and electrical properties. In such a case, the oxide structure can be broken down to reform an unmodified liquid metal alloy, which can then be reprocessed to form “new” MG5, or other formulations. The method makes use of aggressive mixing in acidic solution to break down the gallium oxide, as described below.

### Acid Treatment of Reclaimed MG5

Reclaimed MG5 gel was placed in a bath of 3M hydrochloric acid (HCl) solution. Initially, the hydrochloric acid appeared to have little impact on the mechanical properties of the gel. This contrasts with liquid metal, which will immediately respond to hydrochloric acid. When exposed to hydrochloric acid, the gallium oxide on the surface of the MG5 reacts to form gallium chloride, primarily via the following reaction:

Ga₂O₃+6HCl→2GaCl₃+3H₂O

Removal of the gallium oxide leaves the high surface tension of the liquid metal alloy as the dominant mechanical force. This results in the liquid metal alloy tending to bead up in as close to a spherical shape as possible, and forcing any particulates inside the metal to the exterior.

To achieve this result with the Reclaimed MG5, a stir bar was used in the bath spinning at 500 rpm to mix the solution of the MG5 gel and acid. Initially, the metal alloy is not impacted by the acid. The metal alloy appears shiny and still exhibits the characteristic mechanical properties of a moldable gel with high viscosity. After two days of mixing, it was observed that the MG5 gel structure had broken down. After this mixing, the metal alloy component took on a roughly spherical shape, more characteristic of liquid metal alloy in an acidic solution. Particles were observed floating throughout the solution.

### Recovering Liquid Metal Alloy

Initial experiments (prior to the experiment described as Experiment 3 herein) resulted in 66 wt. % retrieval of the initial liquid metal alloy used to form the MG. Upon implementing the acid treatment technique described in this Experiment 3, greater than 80 wt. % retrieval of the initial liquid metal used to form the MG5 was achieved.

No harmful or toxic byproducts were produced, even the “waste” material filtered from the acidic solution being non-toxic and non-hazardous materials in very small quantities. Moreover, the acidic solution was not substantially degraded and could be used for processing further reclaimed deformable conductive material from other discarded circuit layups.

Thus, the above methods (such as the manufacturing process described above with respect to FIGS. 1-17, the reclaiming process described above with respect to FIG. 27, the recycling process describe above with respect to FIG. 28, and/or the acid stirring technique described with respect to Example 3) can enable the recovery of electric components, reprocessing of layer material(s), and reprocessing of conductive material from discarded circuit assemblies. The recovered and reprocessed material can be re-used to make new circuit assemblies.

### Example 4

The liquid metal alloy recovered in Example 3 may be used as a basis for fabricating more deformable conductive material (e.g., new MG5 or another deformable conductive material), It is anticipated that with further refinement of the acid treatment method, for example, using the same fundamental principles augmented by the development of bespoke equipment, substantially all the liquid metal may be reclaimed.

### Example 5

### Reclamation Efficiency of Circuit Assembly Components

Two highly-efficient circuit assemblies, embodied as two sensors, were manufactured using the principles taught herein. Various tables and explanations are provided to summarize the reclamation efficiency for various components thereof:

Table 1 below summarizes the weight of the total weight of all the unprocessed layers used to make the circuit assembly (stacked layers and release layers) compared to the weight of just the release layers.

TABLE 2
Weight of All Layers Prior to Processing
vs. Weight of Release Layers

| | |
|---|---|
| Total Weight of All Layers (unprocessed) | 11.470 g (2 assemblies) |
| Total Weight of Only Release Layers (waste) | 4.077 g (2 assemblies) |
| Total Weight of Materials that Proceed to the | 7.393 g (2 assemblies) |
| Next Stage of Processing | |

Thus, 35.5 wt. % of the initial materials layer are waste in the form of release liners while 64 wt. % of material moves into the next stage.

Table 3 below shows the total amount of TPU material used to form the stacked layers compared to the weight of the material trimmed from the TPU material from the circuit assemblies.

TABLE 3
Weight of TPU Layer Material Prior to Processing vs. Weight
of Excess TPU Material Cut to from the Circuit Assemblies

| | |
|---|---|
| Total amount of TPU used | 4.485 g (2 assemblies) |
| Excess TPU cut from circuit assembly | 1.390 g (2 assemblies) |
| Amount of TPC retained in circuit | 3.095 g (2 assemblies) |
| assembly | 1.548 g (ave. per 1 assembly) |

Thus, for every 4.485 g of TPU used, 1.39 g is “excess.” In other words, for every 1 g of TPU used, see 0.31 g of excess TPU is formed. However, the TPC may be fully reclaimed and used to make additional circuit assemblies.

Table 4 below shows the weight of the circuit assembly after the MG5 deformable conductive material is added compared to the weight of the circuit assembly prior to MG5 addition. Additionally, Table 5 shows, per sensor, the amount of MG5 actually used in the circuit assembly (calculated based on Table 4), the amount of total MG5 typically deposited during the manufacturing process, and therefore, the amount of excess MG5.

TABLE 4
Weight of Circuit Assembly with MG5 added vs.
Weight of Circuit Assembly without MG5 added

| | |
|---|---|
| Circuit Assembly with MG | 4.6897 g (2 assemblies) |
| Circuit Assembly without MG | 4.6321 g (2 assemblies) |
| Amount of MG5 retained in circuit | 0.0576 g (2 assemblies) |
| assembly | 0.0288 g (ave. per 1 assembly) |

TABLE 5
Weight MG5 in Trace (per sensor), Weight of MG5 Typically
Deposited During Manufacturing (per sensor), and Excess
MG5 Used During Manufacturing (per sensor)

| | |
|---|---|
| MG5 in trace | 0.0288 g (per 1 assembly) |
| MG5 typically deposited | 0.4637 g (per 1 assembly) |
| Excess MG5 used | 0.4349 g (per 1 assembly) |

Thus, for every 28.8 mg of product that ultimately ends up in the sensor there is 435 mg of excess MG5 that is used. In other words, for every 1 mg of MG5 in the final circuit assembly, 0.015 g of excess MG5 is used. However, the excess MG5 may be substantially, reclaimed and used in subsequent circuit assembly manufacturing operations.

Table 6 below shows the total weight of the final circuit assembly components.

TABLE 6
Total Weight of the Final Circuit Assembly Components

| Component | Weight (g) | Weight % |
|---|---|---|
| TPU layers | 1.413 | 83.71% |
| Thermoset B-Stage resin as | 0.192 | 11.37% |
| adhesive | | |
| Electric Component | 0.0546 | 3.23% |
| MG5 | 0.0288 | 1.71% |
| Total | 1.688 | 100.0% |

Notably, the components of the circuit assembly that can be reclaimed using the methods described herein include the TPC layers (83.71 wt. %), the electrical component (3.23 wt. %) and the MG5 (1.71 wt. %). These components make up 88.65% of the circuit assembly, by weight. Additionally, in some aspects, the thermoset adhesive may be reground and recycled.

Also notable was that the circuit assembly included only 1.71% deformable conductive material (MG5), and there was substantially no waste with respect to the deformable conductive material since the “excess” conductive material is fully reclaimable and can be used to manufacturing additional circuit assemblies.

### Example 6

It is contemplated that typical circuit assemblies may include a maximum of 10 wt, % of deformable conductive material, such as, for example, a maximum of 9 wt. %, 8 wt, %, 7 wt. %, 6 wt. %, 5 wt, %, 4 wt. %, 3 wt. %, 2 wt, %, or 1 wt, % of deformable conductive material in the final assembly. Additionally, no less than 95% “excess” deformable conductive material, such as, for example 96 wt. %, 97 wt. %, 98 wt. %, 99 wt. %, 99.5 wt, %, or 99.9 wt. % of excess deformable conductive material may be collected from the manufacturing operation and used for future manufacturing operations.

Various aspects of the subject matter described herein are set out in the following numbered clauses:

Clause 1: A method for reclaiming material from a highly sustainable circuit assembly including an electrical component, a substrate layer, and a deformable conductive material, the method including: removing the electrical component from the circuit assembly; heating the highly sustainable circuit assembly to a melting temperature of the substrate layer to form a melted substrate layer; and separating the deformable conductive material from the melted substrate layer to obtain reclaimed deformable conductive material and reclaimed substrate layer material.

Clause 2: The method according to clause 1, wherein the highly sustainable circuit assembly further includes a stacked layer, the method further including: heating the highly sustainable circuit assembly to a melting temperature of the stacked layer to form a melted stacked layer; and separating the deformable conductive material from the melted stacked layer to obtain reclaimed deformable conductive material and reclaimed stacked layer material.

Clause 3: The method according to any of clauses 1-2, wherein the circuit assembly includes an encapsulant material, the method further including: heating the circuit assembly to a melting temperature of the encapsulant material; wherein removing the electrical component from the circuit assembly occurs after heating the circuit assembly to the glass transition temperature of the encapsulant material.

Clause 4: The method according to any of clauses 1-3, wherein the circuit assembly includes an adhesive material, the method further including: heating the circuit assembly to a glass transition temperature of the adhesive material; wherein removing the electrical component from the circuit assembly occurs after heating the circuit assembly to the glass transition temperature of the adhesive material.

Clause 5: The method according to any of clauses 1-4, wherein the deformable conductive material includes a conductive gel.

Clause 6: The method according to any of clauses 1-5, wherein the deformable conductive material includes a gallium alloy.

Clause 7: The method according to any of clauses 1-6, further including recycling the reclaimed deformable conductive material.

Clause 8: A method for recycling a reclaimed deformable conductive material including: providing a reclaimed deformable conductive material including a metal alloy and a metal oxide formed from exposure of the metal alloy to air; exposing the reclaimed deformable conductive material to an acid solution thereby reacting the metal oxide with the acid solution to obtain a pure liquid metal alloy; removing the pure liquid metal alloy from the acid solution.

Clause 9: The method according to clause 8, further including: manufacturing new deformable conductive material from the pure liquid metal alloy.

Clause 10: The method according to any of clauses clause 8-9, wherein exposing the reclaimed deformable conductive material to an acid solution includes mixing the deformable conductive material in the acid solution to obtain the pure liquid metal alloy.

Clause 11: The method according to any of clauses clause 8-10, wherein the amount of pure liquid metal alloy removed from the acid solution is no less than 55 wt. % of the metal alloy used to originally manufacture the reclaimed deformable conductive material.

Clause 12: The method according to any of clauses 8-11, wherein the amount of pure liquid metal alloy removed from the acid solution is no less than 80 wt. % of the metal alloy used to originally manufacture the reclaimed deformable conductive material.

Clause 13: The method according to any of clauses clause 8-12, wherein the reclaimed deformable conductive material includes microparticles; and wherein mixing the deformable conductive material in the acid solution removes the microparticles to obtain the pure liquid metal alloy.

Clause 14: The method according to any of clauses 8-13, wherein mixing the deformable conductive material in the acid solution to obtain the pure liquid metal alloy includes mixing the deformable conductive material in the acid solution for no less than two days.

Clause 15: The method according to any of clauses 8-14, wherein the metal alloy includes a gallium-indium-tin alloy; and wherein the metal oxide includes gallium oxide.

Clause 16: A highly sustainable circuit assembly including: a substrate; and a pattern of contact points supported by the substrate, the pattern of contact points configured to correspond to at least one terminal of an electrical component, the pattern of contact points including a deformable conductive material; wherein the deformable conductive material includes a readily reclaimable material.

Clause 17: The highly sustainable circuit assembly of clause 16, wherein the deformable conductive material includes a readily recyclable material.

Clause 18: The highly sustainable circuit assembly of any of clauses 16-17, wherein the substrate includes a readily reclaimable material, and wherein the substrate layer includes a readily recyclable material.

Clause 19: The highly sustainable circuit assembly of any of clauses 16-18, wherein the deformable conductive material is configured to adhere to at least one terminal of the electrical component thereby electrically coupling at least a portion of the pattern of contact points to at least one terminal of the electrical component.

Clause 20: The highly sustainable circuit assembly of any of clauses 16-19, wherein supporting the electrical component on the circuit assembly causes the deformable conductive material to conform to a shape of at least one terminal of the electrical component.

Clause 21: The highly sustainable circuit assembly of any of clauses 16-20, wherein the pattern of contact points are formed on a surface of the substrate layer.

Clause 22: The highly sustainable circuit assembly of any of clauses 16-21, wherein the pattern of contact points are at least partially recessed in the substrate layer.

Clause 23: The highly sustainable circuit assembly of any of clauses 16-22, wherein the substrate includes a flexible and/or stretchable material.

Clause 24: The highly sustainable circuit assembly of any of clauses 16-23, further including an insert layer, wherein the insert layer is configured to: prevent flexing and/or stretching of a portion of the substrate layer proximate to the pattern of contact points;

dissipate heat from the electrical component; adhere the electrical component to the substrate layer; or a combination thereof.

Clause 25: The highly sustainable circuit assembly of any of clauses 16-24, further including a pattern of conductive traces supported by the substrate layer, the pattern of conductive traces electrically coupled to the pattern of contact points, the pattern of contact points including the deformable conductive material.

Clause 26: The highly sustainable circuit assembly of any of clauses 16-25, wherein the deformable conductive material includes a conductive gel.

Clause 27: The highly sustainable circuit assembly of any of clauses 16-26, wherein the deformable conductive material includes a gallium alloy.

Clause 28: The highly sustainable circuit assembly of any of clauses 16-27, further including the electrical component.

Clause 29: A method for manufacturing a highly sustainable circuit assembly including: providing a substrate layer; and depositing a deformable conductive material to the substrate layer to form a pattern of contacts that correspond to at least one terminal of an electrical component; wherein the deformable conductive material includes a readily reclaimable material.

Clause 30: The method of clause 29, wherein the deformable conductive material includes a readily recyclable material.

Clause 31: The method of any of clauses 29-30, wherein the substrate layer includes a readily reclaimable material; and wherein the substrate layer includes a readily recyclable material.

Clause 32: The method of any of clauses 29-31, further including bringing the electrical component proximate to the substrate layer; and adhering the deformable conductive material to the at least one terminal of the electrical component thereby forming an ohmic contact between at least a portion of the pattern of contacts and the at least one terminal of the electrical component; wherein brining the electrical component proximate to the substrate layer causes the deformable conductive material to conform to a shape of the at least one terminal of the electrical component.

Clause 33: The method of any of clauses 29-32, further including: securing the electrical component to a layer of adhesive attached to a surface of the substrate layer.

Clause 34: The method of any of clauses 29-33, further including: covering at least a portion of the circuit assembly with an encapsulant.

Clause 35: The method of any of clauses 29-34, further including: attaching the electrical component directly to a surface of the substrate layer.

Clause 36: The method of any of clauses 29-35, attaching an insert layer to the substrate layer, wherein the insert layer is configured to: prevent flexing and/or stretching of a portion of the substrate layer proximate to the pattern of contact points; dissipate heat from the electrical component; adhere the electrical component to the substrate layer; or a combination thereof.

Clause 37: The method of any of clauses 29-36, wherein depositing the deformable conductive material to the substrate layer to form the pattern of contacts further includes: depositing the deformable conductive material such that the deformable conductive material protrudes from a surface of the substrate layer

Clause 38: The method of any of clauses 29-37, wherein depositing the deformable conductive material to the substrate layer to form the pattern of contacts further includes: at least partially filling a recess formed in the substrate layer with the deformable conductive material.

Clause 39: The method of any of clauses 29-38, further including: depositing a deformable conductive material to the substrate layer to form a pattern of conductive traces electrically coupled to the pattern of contact points.

Clause 40: The method of any of clauses 29-39, wherein the substrate layer includes a flexible or stretchable material.

Clause 41: The method of any of clauses 29-40, wherein the deformable conductive material includes a conductive gel.

Clause 42: The method of any of clauses 29-41, wherein the deformable conductive material includes a gallium alloy.

Clause 43: A highly sustainable circuit assembly including: a substrate layer; a first stacked layer including a first pattern of passages formed in the first stacked layer, the first pattern of passages extending through a thickness of the first stacked layer, the first pattern of passages including a deformable conductive material; wherein the deformable conductive material includes a readily reclaimable material.

Clause 44: The circuit assembly of clause 43, wherein the deformable conductive material includes a readily recyclable material.

Clause 45: The circuit assembly of any of clauses 43-44, wherein the substrate layer includes a first material; wherein the first stacked layer includes the first material; wherein the first material is a readily reclaimable material; and wherein the first material is a readily recyclable material.

Clause 46: The circuit assembly of any of clauses 43-45, wherein the first stacked layer is bonded to the substrate layer.

Clause 47: The circuit assembly of any of clauses 43-46, wherein the first stacked layer includes: a first surface adjacent to the substrate layer; and a second surface opposite the first surface; wherein a surface of the deformable conductive material is flush with the second surface of the first stacked layer.

Clause 48: The circuit assembly of any of clauses 43-47, wherein a surface of the deformable conductive material protrudes beyond a surface of the first stacked layer.

Clause 49: The circuit assembly of any of clauses 43-48, wherein the first pact of passages including the deformable conductive material includes: a pattern of contact points configured to correspond to at least one terminal of an electrical component; a pattern of tracers; or a combination thereof.

Clause 50: The circuit assembly of any of clauses 43-49, further including the electrical component.

Clause 51: The circuit assembly of any of clauses 43-50, further including: a second stacked layer including a second pattern of passages formed in the second stacked layer, the second pattern of passages extending through a thickness of the second stacked layer, the third pattern of passages including the deformable conductive material.

Clause 52: The circuit assembly of any of clauses 43-51, further including a sublayer interposed between the first stacked layer and the second stacked layer, the sublayer including a pattern of conductive elements.

Clause 53: The circuit assembly of any of clauses 43-52, wherein the pattern of conductive elements are electrically coupled to the second pattern of passages extending through the thickness of the second stacked layer; and wherein the second pattern of passages are configured to correspond with at least one terminal of an electrical component.

Clause 54: The circuit assembly of any of clauses 43-53, wherein a first portion of the second pattern of passages aligns with a first portion of the first pattern of passages; and wherein the deformable conductive material forms a continuous structure extending from the first portion of the first pattern of passages to the first portion of the second pattern of passages.

Clause 55: The circuit assembly of any of clauses 43-54, further including: a third stacked layer including a third pattern of passages formed in the third stacked layer, the third pattern of passages extending through a thickness of the third stacked layer, the third pattern of passages including the deformable conductive material.

Clause 56: The circuit assembly of any of clauses 43-55, wherein a first portion of the third pattern of passages aligns with a second portion of the second pattern of passages; and wherein the deformable conductive material forms a continuous structure extending from the first portion of the first pattern of passages to the first portion of the third pattern of passages.

Clause 57: The circuit assembly of any of clauses 43-56, further including: a fourth stacked layer including a fourth pattern of passages formed in the fourth stacked layer, the fourth pattern of passages extending through a thickness of the fourth stacked layer, the fourth pattern of passages including the deformable conductive material.

Clause 58: The circuit assembly of any of clauses 43-57, wherein a first portion of the fourth pattern of passages aligns with a second portion of the third pattern of passages; and wherein the deformable conductive material forms a continuous structure extending from the first portion of the first pattern of passages to the first portion of the fourth pattern of passages.

Clause 59: The circuit assembly of any of clauses 43-58, wherein the deformable conductive material includes a conductive gel.

Clause 60: The circuit assembly of any of clauses 43-59, wherein the deformable conductive material includes a gallium alloy.

Clause 61: A method for manufacturing a highly sustainable circuit assembly including: providing a substrate layer; placing a first stacked layer on a surface of the substrate layer, the first stacked layer including a first pattern of passages formed in the first stacked layer, the first pattern of passages extending through a thickness of the first stacked layer; over-filling the first pattern of passages with a deformable conductive material; removing excess deformable conductive material from the circuit assembly; and collecting the excess deformable conductive material.

Clause 62: The method of clauses 61, using the collected excess deformable conductive material to fill a second pattern of passages included in a second stacked layer; using the collected excess deformable conductive material to manufacture a different circuit assembly; or a combination thereof.

Clause 63: The method of any of clauses 61-62, further including: bonding the first stacked layer to the substrate layer.

Clause 64: The method of any of clauses 61-63, wherein removing excess deformable conductive material from the circuit assembly includes wiping excess deformable conductive material from a release liner attached to a surface of the first stacked layer, the method further including: removing the release liner from a surface of the first stacked layer.

Clause 65: The method of any of clauses 61-64, wherein removing excess deformable conductive material from the circuit assembly includes wiping excess deformable conductive material from a surface of the first stacked layer.

Clause 66: The method of any of clauses 61-65, further including: attaching an electrical component to the circuit assembly, wherein at least one terminal of the electrical component corresponds to the first pattern of passages formed in the first stacked layer.

Clause 67: The method of any of clauses 61-66, further including: placing a second stacked layer on a surface of the first stacked layer, the second stacked layer including a second pattern of passages formed in the second stacked layer, the second pattern of passages extending through a thickness of the second stacked layer; over-filling the second pattern of passages with the deformable conductive material; removing excess deformable conductive material from the circuit assembly; and collecting the excess deformable conductive material.

Clause 68: The method of any of clauses 61-67, further including: interposing a sublayer between the first stacked layer and the second stacked layer, the sublayer including a pattern of conductive elements.

Clause 69: The method of any of clauses 61-68, wherein the second pattern of passages are configured to correspond with at least one terminal of an electrical component, the method further including: electrically coupling the pattern of conductive elements to the deformable conductive material filled in the second pattern of passages.

Clause 70: The method of any of clauses 61-69, wherein placing the second stacked layer on the surface of the first stacked layer includes aligning a first portion of the second pattern of passages with a first portion of the first pattern of passages; and wherein over-filling the second pattern of passages with the deformable conductive material includes forming a continuous structure extending from the first portion of the first pattern of passages to the first portion of the second pattern of passages.

Clause 71: The method of any of clauses 61-70, further including: placing a third stacked layer on a surface of the second stacked layer, the third stacked layer including a third pattern of passages formed in the third stacked layer, the third pattern of passages extending through a thickness of the third stacked layer; over-filling the third pattern of passages with the deformable conductive material; removing excess deformable conductive material from the circuit assembly; and collecting the excess deformable conductive material.

Clause 72: The method of any of clauses 61-71, wherein placing the third stacked layer on the surface of the second stacked layer includes aligning a first portion of the third pattern of passages with a second portion of the second pattern of passages; and wherein over-filling the third pattern of passages with the deformable conductive material includes forming a continuous structure extending from the first portion of the first pattern of passages to the first portion of the third pattern of passages.

Clause 73: The method of any of clauses 61-72, further including: placing a fourth stacked layer on a surface of the third stacked layer, the fourth stacked layer including a fourth pattern of passages formed in the fourth stacked layer, the fourth pattern of passages extending through a thickness of the fourth stacked layer; over-filling the fourth pattern of passages with the deformable conductive material; removing excess deformable conductive material from the circuit assembly; and collecting the excess deformable conductive material.

Clause 74: The method of any of clauses 61-73, wherein placing the fourth stacked layer on the surface of the third stacked layer includes aligning a first portion of the fourth pattern of passages with a second portion of the third pattern of passages; and wherein over-filling the fourth pattern of passages with the deformable conductive material includes forming a continuous structure extending from the first portion of the first pattern of passages to the first portion of the fourth pattern of passages.

Clause 75: The method of any of clauses 61-74, wherein the deformable conductive material includes a conductive gel.

Clause 76: The method of any of clauses 61-75, wherein the deformable conductive material includes a gallium alloy.

Clause 77: A highly sustainable circuit layup may include a non-toxic and readily reclaimable deformable conductive material in combination with at least one layer of a readily recyclable material. The conductive material may form a pattern of reusable traces and/or contact points on the layer. The method of forming the reusable traces on the layer may include one operation, produces substantially no waste (toxic or otherwise), and consumes no additional natural resources apart from those that constitute the layup materials. The method consumes substantially less energy compared to methods used to produce conventional circuit boards.

Clause 78: A highly sustainable circuit assembly may include at least one electric component having terminals arranged in a pattern corresponding to a pattern of contact points of the circuit layup. The electric component may have one or more terminals contacting one or more contact points. The electric component is assembled to the layup using a method that provides a reliable electrical connection without the need for soldering, eliminates the need for substantial energy consumption, produces substantially no waste, and emits substantially no volatile organic compounds (VOC's).

Clause 79: A highly sustainable circuit layup may be formed from at least one stack of layers including at least one substrate layer, one or more stencil layers, and one or more insulation layers. One or more of the layers in the stack may be formed from a readily recyclable material. The stack of layers may include at least one pattern of reusable traces and/or contact points and/or vias formed from a non-toxic and readily reclaimable conductive material. The pattern of reusable conductive trace may be interconnected with the pattern of contact points and/or vias. A first pattern of reusable traces, vias, and contact points may be formed on or recessed into a surface of the substrate layer. One or more stencil layers may be supported by the substrate layer with a second pattern of reusable traces and/or contact points and/or vias extending through the entire thickness of the stencil layer. At least a portion of the stencil layer pattern may correspond to the substrate layer pattern. At least one insulation layer may be supported by the substrate and/or at least one stencil layer. The insulation layer may have a pattern of contact points and/or vias on or extending through a surface of the insulation layer. At least a portion of the insulation layer pattern may correspond the substrate and/or stencil layer pattern. The conductive material may be deposited to one or more layers of the stack in a single operation that produces substantially no waste (toxic or otherwise), consumes no additional natural resources apart from those that constitute the layup materials, uses comparatively little energy, and emits substantially no VOC's. The various layers may be joined together to form the stack. The circuit layup may include multiple stacks, and two or more stacks may be joined together. Vias and contact points from one stack may be in communication with vias and contact points from another stack thereby providing communication between the stacks. Vias may extend through combinations of one or more of the substrate, stencil and insulation layers of each stack to provide communication between the reusable traces of the stacks.

Clause 80: A highly sustainable circuit layup or circuit assembly as described above may optionally include an encapsulant covering at least a portion of an electric component, vias, and/or contact points. The encapsulant may be formed from a readily recyclable material that may be like or the same as one or more of the layers of a layup or stack.

Clause 81: The substrate, stencil, and insulation layers may include a flexible material. The layers may include a stretchable material. At least a portion of one of the layers may have an adhesive property. The layers may be joined together by the adhesive property.

Clause 82: At least one electric device may include a surface mount component. At least one electric device may include an integrated circuit in a package. At least one electric device may include a bare integrated circuit die, At least one electric component may be attached to the circuit layup by the adhesive property of one of the layers, or may be attached to one of the layers by an adhesive.

Clause 83: At least one electric component may be attached to the insulation layer. The insulation layer may have an adhesive property sufficient to reliably attach the electric component to the circuit layup. The conductive material may be deformable and have a adhesion characteristic that provides a reliable electrical connection between at least one contact point of the circuit layup and at least one terminal of the electric component without the need for soldering and eliminating the need for substantial energy consumption, producing substantially no waste, and emitting substantially no volatile organic compounds (VOC's).

Clause 84: A method may include providing a substrate layer, forming one or more passages in the substrate layer, depositing a deformable conductive material in at least one of the passages, and stacking an insulation layer on the substrate layer, wherein the insulation layer at least partially encloses the deformable conductive material. Depositing the deformable conductive material in at least one of the passages may include wiping a volume of the conductive material over at least one passage removing excess deformable conductive material from the surrounding substrate surface.

Clause 85: A method may include providing a substrate layer, and optionally forming one or more passages in a substrate layer and depositing a deformable conductive material in at least one of the substrate layer passages, sequentially stacking at least one stencil layer having one or more passages over the substrate layer, after stacking each stencil layer depositing the deformable conductive material in at least one of that stencil layer's passages, and stacking an insulation layer on the last-stacked stencil layer. At least one of the passages in each stencil layer may pass through the entire thickness of that layer. Successively stacked stencil layers may at least partially enclose the deformable conductive material of each a preceding layer. The insulation layer at least partially encloses the deformable conductive material in the at least one passage of the last-stacked stencil layer. Depositing the deformable conductive material may include wiping a volume of the conductive material over at least one passage removing excess deformable conductive material from the surrounding surface of the layer in which the passage is formed.

Clause 86: The substrate surface and at least one stencil layer surfaces may include a release layer. Release layers may be removed after deformable conductive material is deposited on the respective surface layers.

Clause 87: At least one of the passages in the substrate layer or at least one stencil layer may communicate with the at least one passage of another layer. Passages in stencil layers may pass through the layer's entire thickness.

Clause 88: A method may include forming at least one contact point on a circuit layup, the contact point including a deformable conductive material with a adhesion characteristic, and supporting an electric component on the circuit layup, the electric component having at least one terminal, wherein at least one terminal of the electric component contacts at least one of the contact points to form at least one electrical connection between the electric component and the contact point. At least one terminal may include multiple terminals arranged in a pattern, at least one contact point may include multiple contact points including the deformable conductive material and arranged in a pattern corresponding to the pattern of terminals of the electric component, and the multiple terminals of the electric component may contact the multiple contact points, wherein the adhesion characteristic of the deformable conductor provides a reliable electrical connection between the electric component and the contact points.

Clause 89: A method may include heating a circuit assembly to a melting temperature of an encapsulation material, extracting electric components, heating the circuit assembly to the melting temperature one or more of a substrate, stencil and insulation layers, separating a conductive material from the circuit assembly, and purifying the conductive material. The method may further include the steps of re-using the electric components, reprocessing the layer material(s) and the conductive material for re-use.

Clause 90: A method for making a circuit layup may include providing a substrate layer, forming one or more passages in the substrate layer, collecting scrap material generated from the substrate layer and passage formation steps, depositing a deformable conductive material in at least one of the passages, providing an insulation layer and stacking the insulation layer on the substrate layer, collecting scrap material generated from the insulation layer providing steps, wherein depositing the deformable conductive material in at least one of the passages may include wiping a volume of the conductive material over at least one passage removing excess deformable conductive material from the surrounding substrate surface, the insulation layer at least partially encloses the deformable conductive material, and the substrate and insulation layer scrap is reprocessed and the excess conductive material is included in making one or more subsequent circuit layups.

Clause 91: A method for manufacturing a circuit assembly including: providing a substrate layer including a substrate material; placing a stencil including a stencil material on a surface of the substrate layer, wherein the stencil has a thickness and a pattern of passages formed therein; depositing a deformable conductive material to at least partially fill the pattern of passages; removing the removable stencil from the surface of the substrate layer to leave a pattern of deformable conductive material formed on the substrate layer, wherein the pattern of deformable conductive material can include at least one gap; covering at least a portion of the pattern of deformable conductive material with a first stacked layer, wherein the first stacked layer is an insulation layer, an encapsulation layer, or a combination thereof; and unitizing the circuit assembly, wherein unitizing the circuit assembly causes the at least one gap to heal.

Clause 92: The method of clause 91, wherein the pattern of passages includes a trace feature having a trace width, a trace flare feature having a trace flare width, a staggered pattern of trace flare features, a tab having a tab width, a via feature having a via diameter, or a combination thereof.

Clause 93: The method of any of clauses 91-92, wherein the deformable conductive material includes a viscosity, and wherein the viscosity is optimized such that the deformable conductive material heals upon the unitization but not such that the deformable conductive material overly deforms and does not achieve an intended pattern.

Clause 94: The method of any of clauses 91-93, wherein an adhesive characteristic and/or a viscosity of the deformable conductive material is optimized such that the deformable conductive material remains on the substrate layer upon removal of the removable stencil and does not adhere to the pattern of passages of the removable stencil thereby lifting the deformable conductive material off of the substrate layer.

Clause 95: The method of any of clauses 91-94, wherein unitizing the circuit assembly comprises heating at least a portion of the circuit assembly.

Clause 96: The method of any of clauses 91-95, wherein unitizing the circuit assembly comprises applying pressure to at least one surface of the circuit assembly.

Clause 97: The method of any of clauses 91-96, wherein the heating and/or applying pressure are optimized such that the deformable conductive material heals upon the unitization but not such that the deformable conductive material overly deforms and does not achieve an intended pattern.

Clause 98: The method of any of clauses 91-97, including providing at least one opening in the first stacked layer, the substrate layer, or a combination thereof.

Clause 99: The method of any of clauses 91-98, wherein the at least one opening is formed prior to unitizing the circuit assembly.

Clause 100: The method of any of clauses 91-99, wherein the at least one opening is formed after unitizing the circuit assembly.

Clause 101: The method of any of clauses 91-100, further including, after covering the at least a portion of the pattern of deformable conductive material with the first stacked layer, placing the removable stencil on the first stacked layer, repeating the steps of depositing the deformable conductive material and removing the removable stencil to form a second pattern of deformable conductive material on the first stacked layer, and covering at least a portion of the second pattern of deformable conductive material with a second stacked layer.

Clause 102: The method of any of clauses 91-101, further including unitizing the circuit assembly including the substrate layer, the first stacked layer, and the second stacked layer, wherein the unitizing causes at least one gap of the second pattern of deformable conductive material formed to heal.

Clause 103: The method of any of clauses 91-102, further including, after covering at least a portion of the second pattern of deformable conductive material with the second stacked layer, placing the removable stencil on the second stacked layer, repeating the steps of depositing the deformable conductive material and removing the removable stencil to form a third pattern of deformable conductive material on the second stacked layer, and covering at least a portion of the third pattern of deformable conductive material with a third stacked layer.

Clause 104: The method of any of clauses 91-103, further including unitizing the circuit assembly including the substrate layer, the first stacked layer, the second stacked layer, and the third stacked layer, wherein the unitizing causes at least one gap of the third pattern of deformable conductive material to heal.

Clause 105: The method of any of clauses 91-104, further including, after covering at least a portion of the third pattern of deformable conductive material with the third stacked layer, repeating the steps of placing the removable stencil, depositing the deformable conductive material, removing the removable stencil, and covering at least a portion of the resulting pattern of deformable conductive material until a desired number of layers has been achieved.

Clause 106: The method of any of clauses 91-107, further including unitizing the circuit assembly including the desired number of layers.

Clause 107: The method of any of clauses 91-106, including attaching an electrical component to the substrate layer and/or a stacked layer.

Clause 108: The method of any of clauses 91-107, wherein the electrical component includes a polyimide flex circuit, a resistor, a capacitor, a processer, a chip, a contact, a pin out, or a connector.

Clause 109: The method of any of clauses 91-108, including attaching a lockout and/or stiffener layer to the circuit assembly.

Clause 110: The method of any of clauses 91-109, wherein attaching the lockout and/or stiffener includes placing the lockout and/or stiffener between two of the layers of the circuit assembly.

Clause 111: The method of any of clauses 91-110, wherein attaching the lockout and/or stiffener includes placing the lockout and/or stiffener on an outer layer of the circuit assembly.

All patents, patent applications, publications, or other disclosure material mentioned herein, are hereby incorporated by reference in their entirety as if each individual reference was expressly incorporated by reference respectively. All references, and any material, or portion thereof, that are said to be incorporated by reference herein are incorporated herein only to the extent that the incorporated material does not conflict with existing definitions, statements, or other disclosure material set forth in this disclosure. As such, and to the extent necessary, the disclosure as set forth herein supersedes any conflicting material incorporated herein by reference and the disclosure expressly set forth in the present application controls.

The present invention has been described with reference to various exemplary and illustrative aspects. The aspects described herein are understood as providing illustrative features of varying detail of various aspects of the disclosed invention; and therefore, unless otherwise specified, it is to be understood that, to the extent possible, one or more features, elements, components, constituents, ingredients, structures, modules, and/or aspects of the disclosed aspects may be combined, separated, interchanged, and/or rearranged with or relative to one or more other features, elements, components, constituents, ingredients, structures, modules, and/or aspects of the disclosed aspects without departing from the scope of the disclosed invention. Accordingly, it will be recognized by persons having ordinary skill in the art that various substitutions, modifications or combinations of any of the exemplary aspects may be made without departing from the scope of the invention. In addition, persons skilled in the art will recognize, or be able to ascertain using no more than routine experimentation, many equivalents to the various aspects of the invention described herein upon review of this specification. Thus, the invention is not limited by the description of the various aspects, but rather by the claims.

Those skilled in the art will recognize that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to claims containing only one such recitation, even when the same claim includes the introductory phrases “one or more” or “at least one” and indefinite articles such as “a” or “an” (e.g., “a” and/or “an” should typically be interpreted to mean “at least one” or “one or more”), the same holds true for the use of definite articles used to introduce claim recitations.

In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

With respect to the appended claims, those skilled in the art will appreciate that recited operations therein may generally be performed in any order. Also, although claim recitations are presented in a sequence(s), it should be understood that the various operations may be performed in other orders than those which are described, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

It is worthy to note that any reference to “one aspect,” “an aspect,” “an exemplification,” “one exemplification,” and the like means that a particular feature, structure, or characteristic described in connection with the aspect is included in at least one aspect. Thus, appearances of the phrases “in one aspect,” “in an aspect,” “in an exemplification,” and “in one exemplification” in various places throughout the specification are not necessarily all referring to the same aspect. Furthermore, the particular features, structures or characteristics may be combined in any suitable manner in one or more aspects.

As used herein, the singular form of “a”, an”, and “the” include the plural references unless the context clearly dictates otherwise.

Directional phrases used herein, such as, for example and without limitation, top, bottom, left, right, lower, upper, front, back, and variations thereof, shall relate to the orientation of the elements shown in the accompanying drawing and are not limiting upon the claims unless otherwise expressly stated.

The terms “about” or “approximately” as used in the present disclosure, unless otherwise specified, means an acceptable error for a particular value as determined by one of ordinary skill in the art, which depends in part on how the value is measured or determined. In certain aspects, the term “about” or “approximately” means within 1, 2, 3, or 4 standard deviations. In certain aspects, the term “about” or “approximately” means within 50%, 200%, 105%, 100%, 9%, 8%, 7%, 6%, 5%, 4%, 3%, 2%, 1%, 0.5%, or 0.05% of a given value or range.

In this specification, unless otherwise indicated, all numerical parameters are to be understood as being prefaced and modified in all instances by the term “about,” in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Any numerical range recited herein includes all sub-ranges subsumed within the recited range. For example, a range of “1 to 100” includes all sub-ranges between (and including) the recited minimum value of 1 and the recited maximum value of 100, that is, having a minimum value equal to or greater than 1 and a maximum value equal to or less than 100. Also, all ranges recited herein are inclusive of the end points of the recited ranges. For example, a range of “1 to 100” includes the end points 1 and 100. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited. All such ranges are inherently described in this specification.

Any patent application, patent, non-patent publication, or other disclosure material referred to in this specification and/or listed in any Application Data Sheet is incorporated by reference herein, to the extent that the incorporated materials is not inconsistent herewith. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system that “comprises,” “has,” “includes” or “contains” one or more elements possesses those one or more elements, but is not limited to possessing only those one or more elements. Likewise, an element of a system, device, or apparatus that “comprises,” “has,” “includes” or “contains” one or more features possesses those one or more features, but is not limited to possessing only those one or more features.

1. A method for manufacturing a circuit assembly, the method comprising:
providing a substrate layer comprising a substrate material;
placing a removable stencil comprising a stencil material on a surface of the substrate layer, wherein the removable stencil has a thickness and a pattern of passages formed therein;
depositing a deformable conductive material to at least partially fill the pattern of passages;
removing the removable stencil from the surface of the substrate layer to leave a first pattern of deformable conductive material formed on the substrate layer, wherein the first pattern of deformable conductive material can comprise at least one gap;
covering at least a portion of the first pattern of deformable conductive material with a first stacked layer, wherein the first stacked layer is an insulation layer, an encapsulation layer, or a combination thereof; and
unitizing the circuit assembly, wherein unitizing the circuit assembly causes the at least one gap to heal.

2. The method of claim 1, wherein the pattern of passages comprises a trace feature having a trace width, a trace flare feature having a trace flare width, a staggered pattern of trace flare features, a tab having a tab width, a via feature having a via diameter, or a combination thereof.

3. The method of claim 1, wherein the deformable conductive material comprises a viscosity, and wherein the viscosity is optimized such that the deformable conductive material heals upon the unitization but not such that the deformable conductive material overly deforms and does not achieve an intended pattern.

4. The method of claim 1, wherein an adhesive characteristic of the deformable conductive material, a viscosity of the deformable conductive material, or a combination thereof are optimized such that the deformable conductive material remains on the substrate layer upon removal of the removable stencil and does not adhere to the pattern of passages of the removable stencil thereby lifting the deformable conductive material off of the substrate layer.

5. The method of claim 1, wherein unitizing the circuit assembly comprises heating at least a portion of the circuit assembly.

6. The method of claim 1, wherein unitizing the circuit assembly comprises applying pressure to at least one surface of the circuit assembly.

7. The method of claim 1, further comprising providing at least one opening in the first stacked layer, the substrate layer, or a combination thereof.

8. The method of claim 1, further comprising, after covering the at least a portion of the first pattern of deformable conductive material with the first stacked layer, placing the removable stencil on the first stacked layer, repeating the steps of depositing the deformable conductive material and removing the removable stencil to form a second pattern of deformable conductive material on the first stacked layer, and covering at least a portion of the second pattern of deformable conductive material with a second stacked layer.

9. The method of claim 8, further comprising unitizing the circuit assembly including the substrate layer, the first stacked layer, and the second stacked layer, wherein the unitizing causes at least one gap of the second pattern of deformable conductive material to heal.

10. The method of claim 8, further comprising, after covering at least a portion of the second pattern of deformable conductive material with the second stacked layer, placing the removable stencil on the second stacked layer, repeating the steps of depositing the deformable conductive material and removing the removable stencil to form a third pattern of deformable conductive material on the second stacked layer, and covering at least a portion of the third pattern of deformable conductive material with a third stacked layer.

11. The method of claim 10, further comprising unitizing the circuit assembly including the substrate layer, the first stacked layer, the second stacked layer, and the third stacked layer, wherein the unitizing causes at least one gap of the third pattern of deformable conductive material to heal.

12. The method claim 10, further comprising, after covering at least a portion of the third pattern of deformable conductive material with the third stacked layer, repeating the steps of placing the removable stencil, depositing the deformable conductive material, removing the removable stencil, and covering at least a portion of the resulting pattern of deformable conductive material until a desired number of layers has been achieved.

13. The method claim 12, further including unitizing the circuit assembly including the desired number of layers.

14. The method of claim 1, further comprising attaching an electrical component to the substrate layer or the first stacked layer.

15. A circuit assembly comprising:
a substrate layer;
a first pattern of deformable conductive material formed on a surface of the substrate layer using a removable stencil; and
a first stacked layer configured to cover at least a portion of the first pattern of deformable conductive material.

16. The circuit assembly of claim 15, wherein the first stacked layer is unitized to a surface of the substrate layer.

17. The circuit assembly of claim 16, further comprising:
a second pattern of deformable conductive material formed on a surface of the first stacked layer; and
a second stacked layer unitized to a surface of the first stacked layer;
wherein the second pattern of deformable conductive material is formed using the removable stencil.

18. The circuit assembly of claim 15, wherein the first pattern of the deformable conductive material comprises:
a pattern of contact points configured to correspond to at least one terminal of an electrical component;
a pattern of traces; or
a combination thereof.

19. The circuit assembly of claim 1, wherein the first pattern of deformable conductive material comprises a conductive gel.

20. The circuit assembly of claim 1, wherein the first pattern of deformable conductive material comprises a gallium alloy.
